(19) United States
(12) Patent Application Publication
(10) Pub. No.: US 2024/0387580 A1
(43) Pub. Date: Nov. 21, 2024

(54) IMAGING APPARATUS AND MANUFACTURING METHOD FOR THE SAME, AND ELECTRONIC EQUIPMENT

(71) Applicant: SONY SEMICONDUCTOR SOLUTIONS CORPORATION, KANAGAWA (JP)

(72) Inventor: TATSUKI MIYAJI, KANAGAWA (JP)

(21) Appl. No.: 18/578,799

(22) PCT Filed: Mar. 16, 2022
(86) PCT No.: PCT/JP2022/011860

§ 371 Date: Jan. 12, 2024

(30) Foreign Application Priority Data
Aug. 3, 2021 (JP) 2021-127741

(51) Int. Cl. H01L 27/146

(52) U.S. Cl. CPC H01L 27/14623; H01L 27/14685

(57) ABSTRACT

An imaging apparatus for which possible defects during manufacturing are suppressed is provided. An imaging apparatus 101 includes a photoelectric converting section 51 that is disposed in a semiconductor substrate 11 and that generates, by photoelectric conversion, charge according to an amount of received light, a charge holding section MEM that is disposed on a first surface 11A side of the photoelectric converting section 51 corresponding to a first surface 11A of the semiconductor substrate 11 opposite to a light incident surface of the semiconductor substrate 11 and that holds the charge transferred from the photoelectric converting section 51, and a light shielding section 12 that is disposed between the photoelectric converting section 51 and the charge holding section MEM and that surrounds at least a part of the charge holding section MEM, and the light shielding section 12 includes an electrically conductive section 12C that is a partial region of the light shielding section 12 and that is electrically conductive with the semiconductor substrate 11.

### TECHNICAL FIELD

The present disclosure relates to an imaging apparatus that performs imaging based on photoelectric conversion, a manufacturing method for the imaging apparatus, and electronic equipment.

### BACKGROUND ART

Global shutter imaging apparatuses that image all pixels at the same timing are known. In an imaging apparatus of this type, each pixel is provided with a charge holding section in which charge generated by a photoelectric converting section is accumulated. For such an imaging apparatus, there has been proposed a technology in which a photoelectric converting section and a charge holding section are laminated, with a light shielding film formed between the photoelectric converting section and the charge holding section, preventing charge noise caused by light having passed through instead of being absorbed by the photoelectric converting section, while reserving the area of the charge holding section (see, for example, PTL 1).

### CITATION LIST

### Patent Literature

[PTL 1]
PCT Patent Publication No. WO2016/136486

### SUMMARY

### Technical Problem

An object of the present disclosure is to provide an imaging apparatus for which possible defects during manufacture are suppressed.

### Solution to Problem

An imaging apparatus according to an aspect of the present disclosure includes a photoelectric converting section that is disposed in a semiconductor substrate and that generates, by photoelectric conversion, charge according to an amount of received light, a charge holding section that is disposed on a first surface side of the photoelectric converting section corresponding to a first surface of the semiconductor substrate opposite to a light incident surface of the semiconductor substrate and that holds the charge transferred from the photoelectric converting section, and a light shielding section that is disposed between the photoelectric converting section and the charge holding section and that surrounds at least a part of the charge holding section. The light shielding section includes an electrically conductive section that is a partial region of the light shielding section and that is electrically conductive with the semiconductor substrate.

The light shielding section may include a horizontal light shielding portion spreading in an in-plane direction of the semiconductor substrate between the photoelectric converting section and the charge holding section, and a vertical light shielding section shaped like a wall that is extending from the first surface of the semiconductor substrate in a depth direction and that is connected to the horizontal light shielding portion. The light shielding section may include a light shielding material section including a conductive light shielding material, and an insulating film covering a periphery of the light shielding material section, and at the electrically conductive section, the light shielding material section may connect to the semiconductor substrate without intervention of the insulating film. The light shielding section may include the electrically conductive section in an internal region spaced from a second surface of the semiconductor substrate that is the light incident surface and from the first surface.

The light shielding section may not include the electrically conductive section in an intra-effective-pixel region that is a region inside an effective pixel region of the imaging apparatus and may include the electrically conductive section in an extra-effective-pixel region that is a region outside the effective pixel region. A sequence of the horizontal light shielding portions of the light shielding section may be disposed from the intra-effective-pixel region to the extra-effective-pixel region.

The electrically conductive section of the light shielding section may include a region where the light shielding material section comes into contact with a high-concentration P type region in the semiconductor substrate. The light shielding section may include the electrically conductive section in an intra-effective-pixel region that is a region inside an effective pixel region of the imaging apparatus, and the electrically conductive section may include a region where the light shielding material section comes into contact with a high-concentration P type region in the semiconductor substrate.

The semiconductor substrate may be a silicon substrate. The light shielding material section may include tungsten, titanium, tantalum, nickel, molybdenum, chromium, iridium, platiniridium, titanium nitride, aluminum, copper, cobalt, or a tungsten silicon compound.

A manufacturing method for an imaging apparatus according to an aspect of the present disclosure includes a photoelectric converting section forming step of forming a photoelectric converting section that generates, by photoelectric conversion, charge according to an amount of received light, a light shielding section forming step of forming a light shielding section on a first surface side of the photoelectric converting section corresponding to a first surface of the semiconductor substrate opposite to a light incident surface of the semiconductor substrate, and a charge holding section forming step of forming a charge holding section on the first surface side of the light shielding section corresponding to the first surface of the semiconductor substrate, the charge holding section being at least partly surrounded by the light shielding section and holding the charge transferred from the photoelectric converting section. The light shielding section includes a light shielding material section including a conductive light shielding material, and an insulating film covering a periphery of the light shielding material section, and is provided at a partial region of the light shielding section with an electrically conductive section at which the light shielding material section connects to the semiconductor substrate without intervention of the insulating film.

The light shielding section forming step may include a cavity section forming step of forming a cavity section including a horizontal cavity portion spreading in an in-plane direction of the semiconductor substrate between the photoelectric converting section and the charge holding section, and a trench portion that is extending from the first surface of the semiconductor substrate in a depth direction and that is connected to the horizontal cavity portion, the cavity section being covered with the insulating film, an insulating film removing step of removing the insulating film in a region corresponding to the electrically conductive section, and a light shielding material filling step of filling the cavity section with a light shielding material constituting the light shielding material section.

The insulating film removing step may include a resist applying step of applying resist to a resist application region that is a partial region of the first surface of the semiconductor substrate, an etching step of removing, by etching, at least a part of the insulating film formed in a portion of the cavity section that is present outside the resist application region, and a resist removing step of removing the resist applied in the resist applying step. The etching step may remove, by anisotropic etching, the insulating film on a bottom surface of the trench portion of the cavity section. The resist applying step may apply the resist in such a manner as to fill a portion of the cavity section that is present in the resist application region, with the resist up to the horizontal cavity portion, and the etching step may remove the insulating film in the cavity section by isotropic etching. The resist application region may include an entire effective pixel region of the imaging apparatus.

Electronic equipment according to an aspect of the present disclosure includes an imaging apparatus, and the imaging apparatus includes a photoelectric converting section that is disposed in a semiconductor substrate and that generates, by photoelectric conversion, charge according to an amount of received light, a charge holding section that is disposed on a first surface side of the photoelectric converting section corresponding to a first surface of the semiconductor substrate opposite to a light incident surface of the semiconductor substrate and that holds the charge transferred from the photoelectric converting section, and a light shielding section that is disposed between the photoelectric converting section and the charge holding section and that surrounds at least a part of the charge holding section. The light shielding section includes an electrically conductive section that is a partial region of the light shielding section and that is electrically conductive with the semiconductor substrate.

### BRIEF DESCRIPTION OF DRAWINGS

FIG. 1 is a block diagram illustrating a schematic configuration of an imaging apparatus according to the present embodiment.

FIG. 2 is an equivalent circuit diagram of a sensor pixel and a readout circuit.

FIG. 3 is a plane layout diagram of a partial pixel region in a pixel array section.

FIG. 4 is a plane layout diagram depicting a pixel region for one pixel and a readout circuit for the pixel region.

FIG. 5 is a longitudinal cross-sectional view illustrating a cross-section structure of the imaging apparatus and depicting an A-A cross section in FIG. 3.

FIG. 6 is a longitudinal cross-sectional view illustrating a cross-section structure of the imaging apparatus and depicting a B-B cross section in FIG. 3.

FIG. 7 is a transverse cross-sectional view illustrating arrangement of a first light shielding section and depicting a C-C cross section in FIG. 3.

FIG. 8 is a transverse cross-sectional view illustrating arrangement of a second light shielding section and an element isolating section and depicting a D-D cross section in FIG. 3.

FIG. 9 is a plane layout diagram depicting the region of an electrically conductive section of the first light shielding section.

FIG. 10 is a longitudinal cross-sectional view illustrating a cross-section structure in a region outside an effective pixel region in the imaging apparatus, and depicting an E-E cross section in FIG. 9

FIG. 11 is a flow diagram illustrating an example of a manufacturing method for the imaging apparatus according to the present embodiment.

FIG. 12A is a longitudinal cross-sectional view illustrating an example of a manufacturing method for the imaging apparatus according to the present embodiment.

FIG. 12B is a longitudinal cross-sectional view continued from FIG. 12A.

FIG. 12C is a longitudinal cross-sectional view continued from FIG. 12B.

FIG. 12D is a longitudinal cross-sectional view continued from FIG. 12C.

FIG. 12E is a longitudinal cross-sectional view continued from FIG. 12D.

FIG. 12F is a longitudinal cross-sectional view continued from FIG. 12E.

FIG. 13 is a flow diagram illustrating an example of a step of forming a first light shielding section.

FIG. 14A is a longitudinal cross-sectional view illustrating an example of a step of forming a cavity section covered with an insulating film.

FIG. 14B is a longitudinal cross-sectional view continued from FIG. 14A.

FIG. 14C is a longitudinal cross-sectional view continued from FIG. 14B.

FIG. 14D is a longitudinal cross-sectional view continued from FIG. 14C.

FIG. 14E is a longitudinal cross-sectional view continued from FIG. 14D.

FIG. 14F is a longitudinal cross-sectional view continued from FIG. 14E.

FIG. 14G is a longitudinal cross-sectional view continued from FIG. 14F.

FIG. 14H is a longitudinal cross-sectional view continued from FIG. 14G.

FIG. 15A is a longitudinal cross-sectional view illustrating an example of a step of removing a part of the insulating film.

FIG. 15B is a longitudinal cross-sectional view continued from FIG. 15A.

FIG. 15C is a longitudinal cross-sectional view continued from FIG. 15B.

FIG. 16 is a plane layout diagram depicting a region to which resist is applied.

FIG. 17A is a longitudinal cross-sectional view depicting an example of a step of filling the cavity section with a light shielding material.

FIG. 17B is a longitudinal cross-sectional view continued from FIG. 17A.

FIG. 18A is a longitudinal cross-sectional view illustrating an example of a step of forming a second light shielding section and an element isolating section.

FIG. 18B is a longitudinal cross-sectional view continued from FIG. 18A.

FIG. 18C is a longitudinal cross-sectional view continued from FIG. 18B.

FIG. 18D is a longitudinal cross-sectional view continued from FIG. 18C.

FIG. 18E is a longitudinal cross-sectional view continued from FIG. 18D.

FIG. 19A is a longitudinal cross-sectional view illustrating a step of forming a first light shielding section of an imaging apparatus according to Variation 1.

FIG. 19B is a longitudinal cross-sectional view continued from FIG. 19A.

FIG. 19C is a longitudinal cross-sectional view continued from FIG. 19B.

FIG. 20A is a longitudinal cross-sectional view illustrating a step of forming a first light shielding section of an imaging apparatus according to Variation 2.

FIG. 20B is a longitudinal cross-sectional view continued from FIG. 20A.

FIG. 20C is a longitudinal cross-sectional view continued from FIG. 20B.

FIG. 21A is a longitudinal cross-sectional view illustrating a step of forming a first light shielding section of an imaging apparatus according to Variation 3.

FIG. 21B is a longitudinal cross-sectional view continued from FIG. 21A.

FIG. 21C is a longitudinal cross-sectional view continued from FIG. 21B.

FIG. 22 is a longitudinal cross-sectional view depicting a cross-section structure of an imaging apparatus according to Variation 4.

FIG. 23 is a block diagram illustrating a configuration example of a camera as electronic equipment.

FIG. 24 is a block diagram depicting an example of schematic configuration of a vehicle control system.

FIG. 25 is a diagram of assistance in explaining an example of installation positions of an outside-vehicle information detecting section and an imaging section.

### DESCRIPTION OF EMBODIMENT

An example of an embodiment (hereinafter referred to as the “present embodiment”) of the present disclosure will hereinafter be described with reference to the drawings. Note that the description is given in the following order.
1. Structure of Imaging Apparatus of Present Embodiment
2. Manufacturing Method for Imaging Apparatus of Present Embodiment
3. Variations
4. Example of Application to Electronic Equipment
5. Example of Application to Mobile Body
6. Conclusion

### 1. Structure of Imaging Apparatus of Present Embodiment

An imaging apparatus of the present embodiment is, for example, a back-illuminated global shutter image sensor including a CMOS (Complementary Metal Oxide Semiconductor) image sensor or the like. The imaging apparatus of the present embodiment receives light from a subject on a pixel-by-pixel basis and photoelectrically converts the light to generate pixel signals that are electrical signals.

The global shutter method starts and ends exposure of all pixels at the same time. Here, all pixels refer to all the pixels forming a valid image and exclude dummy pixels and the like which do not contribute to image formation. Further, in a case where image distortion or exposure time difference is insignificant or small enough to pose no problem, the start or end need not necessarily be simultaneous. For example, the global shutter method also includes a case where an operation of performing simultaneous exposure on every plurality of rows (every several tens of rows or the like) is repeated with the plurality of rows shifted in a row direction for each operation. Further, the global shutter method includes a case of performing simultaneous exposure only at a partial pixel region.

The back-illuminated image sensor is an image sensor including, for each pixel, a photoelectric converting section, such as a photodiode, disposed between a light receiving surface on which light from a subject is incident and a wiring layer provided with wires such as transistors that drive each pixel, the photoelectric converting section receiving light from the subject and converting the light into an electric signal. Note that a technology according to the present disclosure may also be applied to image sensors based on imaging methods other than that of the CMOS image sensor.

### (Block Configuration of Imaging Apparatus 101)

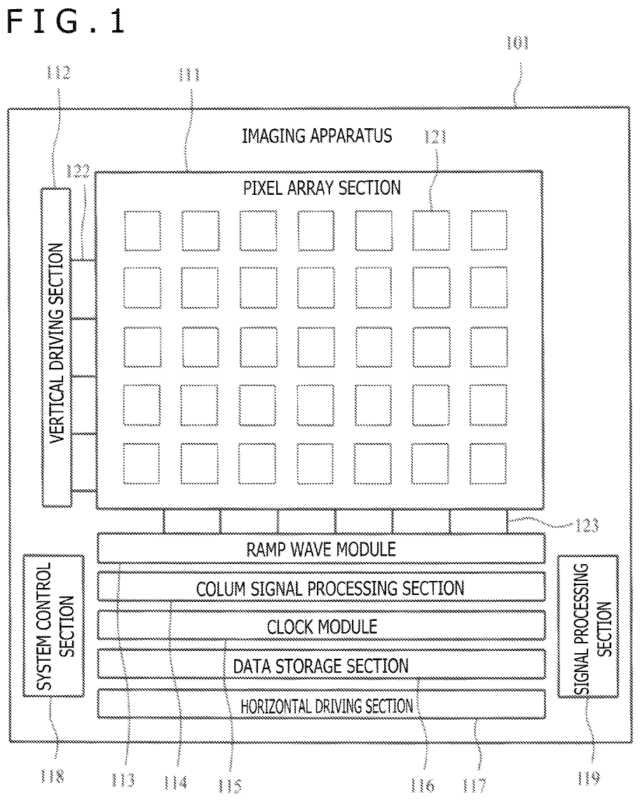

FIG. 1 is a block diagram depicting a schematic configuration of an imaging apparatus 101 of the present embodiment.

As described below, the imaging apparatus 101 of the present embodiment is formed on a semiconductor substrate 11. Thus, in a precise sense, the imaging apparatus 101 is a solid-state imaging apparatus, but is hereinafter simply referred to as the imaging apparatus.

The imaging apparatus 101 includes, for example, a pixel array section 111, a vertical driving section 112, a ramp wave module 113, a column signal processing section 114, a clock module 115, a data storage section 116, a horizontal driving section 117, a system control section 118, and a signal processing section 119.

The pixel array section 111 includes a plurality of sensor pixels 121 each including a photoelectric converting element that generates charge according to the amount of light incident from the subject and accumulates the charge. As depicted in FIG. 1, the plurality of sensor pixels 121 are arranged in a horizontal direction (row direction) and a vertical direction (column direction). The sensor pixels 121 correspond to pixels of the imaging apparatus 101. Pixel information of the sensor pixels 121 is read via a readout circuit 120 described below.

Further, the pixel array section 111 includes pixel driving lines 122 and vertical signal lines 123. The pixel driving line 122 is laid along the row direction for each pixel row including the sensor pixels 121 arranged in line in the row direction. The vertical signal line 123 is laid along a column direction for each pixel column including the sensor pixels 121 arranged in line in the column direction.

The vertical driving section 112 includes a shift register, an address decoder, and the like. The vertical driving section 112 feeds signals and the like to the plurality of sensor pixels 121 via the respective plurality of pixel driving lines 122 to simultaneously drive all of the plurality of sensor pixels 121 in the pixel array section 111 or drive the sensor pixels 121 on a pixel-row-by-pixel-row basis.

The ramp wave module 113 generates a ramp wave signal used for A/D (Analog/Digital) conversion of a pixel signal, and feeds the ramp wave signal to the column signal processing section 114.

The column signal processing section 114 includes a shift register, an address decoder, and the like to execute noise removal processing, correlated double sampling processing, A/D conversion processing, and the like and generate pixel signals. The column signal processing section 114 feeds the pixel signals generated to the signal processing section 119.

The clock module 115 feeds a clock signal for operation to each section of the imaging apparatus 101.

The horizontal driving section 117 sequentially selects, in order, a unit circuit corresponding to a pixel column of the column signal processing section 114. The selective scanning by the horizontal driving section 117 causes pixel signals each subjected to signal processing for a respective one of the unit circuits in the column signal processing section 114 to be output to the signal processing section 119 in order.

The system control section 118 includes a timing generator that generates various timing signals, or the like. According to timing signals generated by the timing generator, the system control section 118 performs driving control on the vertical driving section 112, the ramp wave module 113, the column signal processing section 114, the clock module 115, and the horizontal driving section 117.

The signal processing section 119 executes signal processing such as arithmetic processing on the pixel signals fed from the column signal processing section 114, while temporarily storing data in the data storage section 116 as required. The signal processing section 119 then outputs an image signal including the pixel signals.

The imaging apparatus 101 includes one or a plurality of semiconductor substrates 11. For example, the imaging apparatus 101 can be configured by electrically connecting, by Cu—Cu bonding or the like, the semiconductor substrate 11 provided with the pixel array section 111 to another semiconductor substrate 11 provided with the vertical driving section 112, the ramp wave module 113, the column signal processing section 114, the clock module 115, the data storage section 116, the horizontal driving section 117, the system control section 118, the signal processing section 119, and the like.

### (Circuit Configuration of Readout Circuit 120)

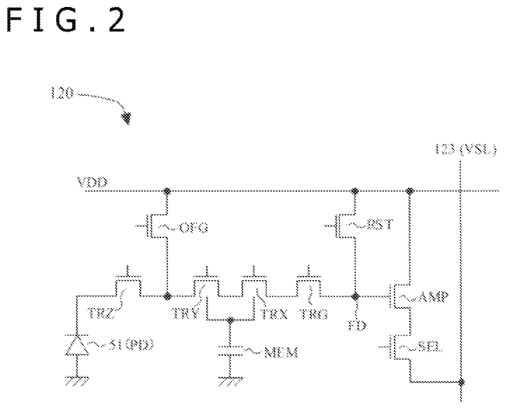

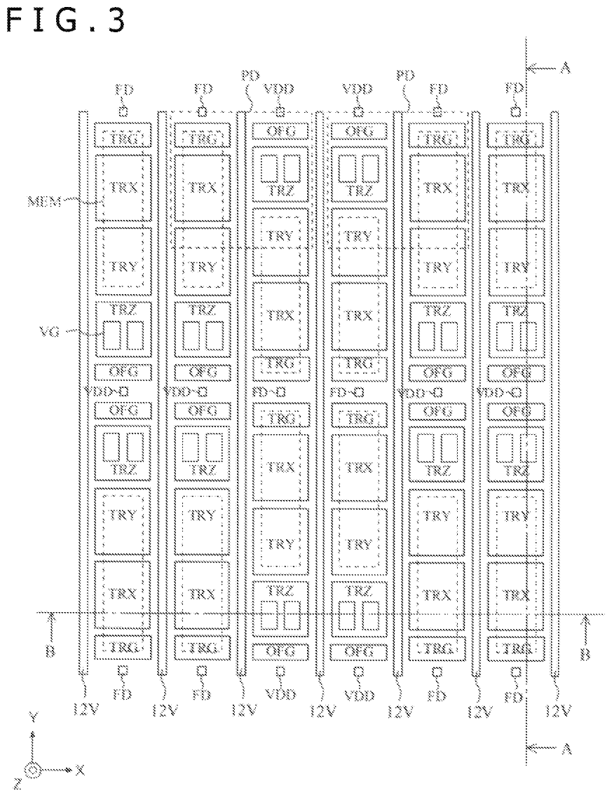

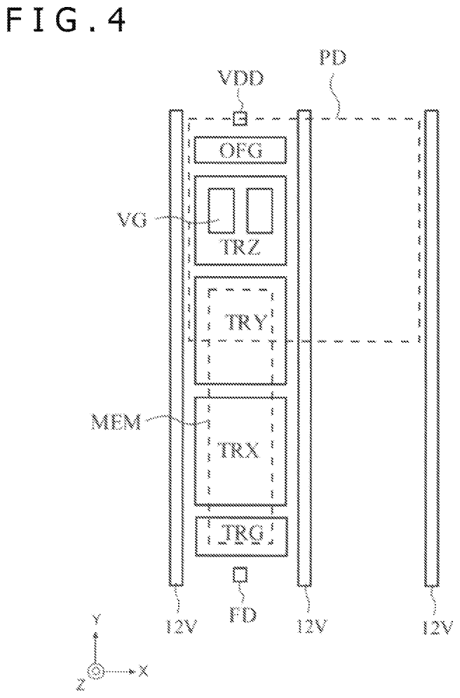

FIG. 2 is an equivalent circuit diagram of the sensor pixel 121 and the readout circuit 120. FIG. 3 is a plane layout diagram of a partial pixel region in the pixel array section 111. FIG. 4 is a plane layout diagram depicting a pixel region for one pixel and the readout circuit 120 for the pixel.

As depicted in FIGS. 2 to 4, the readout circuit 120 includes four transfer transistors TRZ, TRY, TRX, and TRG, a discharge transistor OFG, a reset transistor RST, an amplifying transistor AMP, and a select transistor SEL. These transistors are N type MOS transistors.

The reset transistor RST, the amplifying transistor AMP, and the select transistor SEL are formed on a semiconductor substrate different from the semiconductor substrate 11 on which the pixel array section 111 is disposed, and are laminated together. Accordingly, theses transistors are not depicted in the plane layout diagrams in FIGS. 3 and 4.

An example in which a photodiode PD is used as a photoelectric converting section 51 will be described below.

The photoelectric converting section 51 (PD) generates charge according to the amount of received light by photoelectric conversion.

The transfer transistor TRZ is connected to the photoelectric converting section 51 (PD) in the sensor pixel 121 to transfer, to the transfer transistor TRY, charge (pixel signal) resulting from photoelectric conversion by the photoelectric converting section 51 (PD). The transfer transistor TRZ is a vertical transistor and includes a vertical gate electrode VG.

The transfer transistor TRY transfers, to the transfer transistor TRX, charge transferred from the transfer transistor TRZ. The transfer transistors TRY and TRX may be substituted with one transfer transistor. The transfer transistors TRY and TRX connect to a charge holding section MEM. Control signals applied to gate electrodes of the transfer transistors TRY and TRX control the potential of the charge holding section MEM.

For example, turning on the transfer transistors TRY and TRX increases the potential of the charge holding section MEM, and turning off the transfer transistors TRY and TRX reduces the potential of the charge holding section MEM. Further, for example, turning on the transfer transistors TRZ, TRY, and TRX transfers charge accumulated in the photodiode PD to the charge holding section MEM via the transfer transistors TRZ, TRY, and TRX.

A drain of the transfer transistor TRX is electrically connected to a source of the transfer transistor TRG. Gates of the transfer transistors TRY and TRX are connected to the pixel driving line 122.

The charge holding section MEM is a region where charge generated and accumulated in the photoelectric converting section 51 (PD) is temporarily held in order to realize a global shutter function. The charge holding section MEM holds charge transferred from the photoelectric converting section 51 (PD).

The transfer transistor TRG is connected to and between the transfer transistor TRX and a floating diffusion FD. In response to the control signal applied to the gate electrode, the transfer transistor TRG transfers, to the floating diffusion FD, charge held in the charge holding section MEM.

For example, turning off the transfer transistor TRX and turning on the transfer transistor TRG transfer, to the floating diffusion FD, the charge held in the charge holding section MEM. A drain of the transfer transistor TRG is electrically connected to the floating diffusion FD. A gate of the transfer transistor TRG is connected to the pixel driving line 122.

The floating diffusion FD is a floating diffusion region where charge that is output from the photoelectric converting section 51 (PD) via the transfer transistor TRG is temporarily held. The floating diffusion FD connects, for example, to the reset transistor RST and to the vertical signal line 123 (VSL) via the amplifying transistor AMP and the select transistor SEL.

In response to the control signal applied to the gate electrode, the discharge transistor OFG initializes (resets) the photoelectric converting section 51 (PD). A drain of the discharge transistor OFG is connected to a power supply line VDD. A source of the discharge transistor OFG is connected to and between the transfer transistor TRZ and the transfer transistor TRY.

For example, turning on the transfer transistor TRZ and the discharge transistor OFG resets the potential of the photoelectric converting section 51 (PD) to the potential level of the power supply line VDD. That is, the photoelectric converting section 51 (PD) is initialized. Further, the discharge transistor OFG, for example, forms an overflow path between the transfer transistor TRZ and the power supply line VDD and discharges, to the power supply line VDD, charge overflowing from the photoelectric converting section 51 (PD).

In response to the control signal applied to the gate electrode, the reset transistor RST initializes (resets) each of the regions ranging from the charge holding section MEM to the floating diffusion FD. A drain of the reset transistor RST is connected to the power supply line VDD. A source of the reset transistor RST is connected to the floating diffusion FD.

For example, turning on the transfer transistor TRG and the reset transistor RST resets the potential of the charge holding section MEM and the potential of the floating diffusion FD to the potential level of the power supply line VDD. That is, turning on the reset transistor RST initializes the charge holding section MEM and the floating diffusion FD.

The amplifying transistor AMP includes a gate electrode connected to the floating diffusion FD and a drain connected to the power supply line VDD, to constitute an input section of a source follower circuit that reads out charge obtained by photoelectric conversion in the photoelectric converting section 51 (PD). That is, the amplifying transistor AMP includes a source connected to the vertical signal line 123 (VSL) via the select transistor SEL, to constitute a source follower circuit with a constant current source connected to one end of the vertical signal line 123 (VSL).

The select transistor SEL is connected to and between a source of the amplifying transistor AMP and the vertical signal line 123 (VSL). A gate electrode of the select transistor SEL is fed with a control signal as a select signal. Turning on the control signal brings the select transistor SEL into an electrically conductive state and brings the sensor pixel 121 coupled to the select transistor SEL into a selected state. The sensor pixel 121 in the selected state causes the pixel signal output from the amplifying transistor AMP to be read out into the column signal processing section 114 via the vertical signal line 123 (VSL).

As depicted in FIGS. 3 and 4, the transfer transistors TRG, TRX, TRY, and TRZ and the discharge transistor OFG in the readout circuit 120 of one sensor pixel 121 are arranged in order in a Y direction. The arrangement of the transistors in two sensor pixels 121 adjacent to each other in the Y direction is symmetric with respect to a boundary between the pixels in the Y direction. For the arrangement of the transistors in the readout circuit 120 for two sensor pixels 121 adjacent to each other in an X direction, opposite arrangements and the same arrangements are repeated in an alternate manner.

The charge holding section MEM is disposed below the transfer transistors TRG, TRX, and TRY. Further, the photoelectric converting section 51 (PD) in one sensor pixel 121 is disposed below the transfer transistors TRG, TRX, and TRY of the sensor pixel 121 and below the discharge transistor OFG and the transfer transistors TRZ and TRY of the sensor pixel 121 adjacent to the above-described sensor pixel 121 in the X direction.

The plane layout of the transistors in the readout circuit 120 is not necessarily limited to the plane layout depicted in FIGS. 3 and 4. Variation of arrangement of the transistors in the readout circuit 120 also varies the arrangement positions of the photoelectric converting section 51 (PD) and the charge holding section MEM disposed below the transistors.

### (Cross-Section Structure of Imaging Apparatus 101)

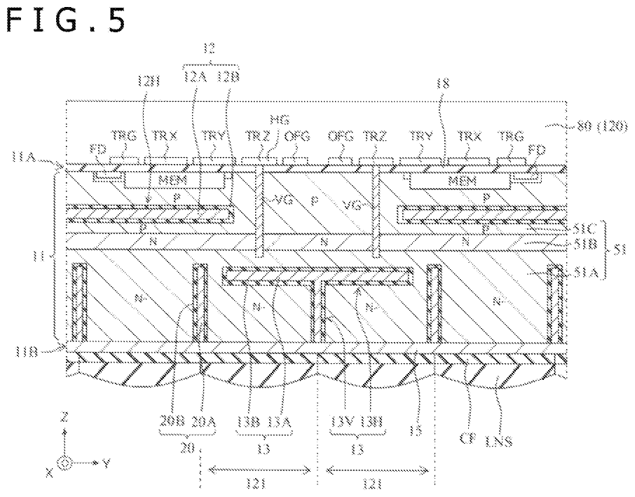

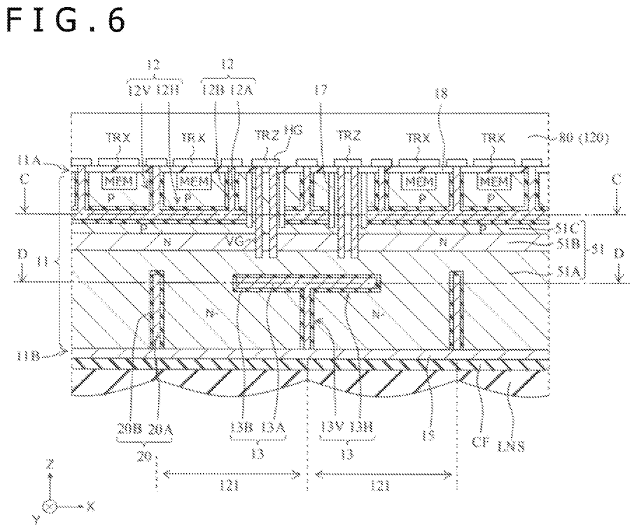

FIG. 5 is a cross-sectional view taken along an A-A direction in FIG. 3. FIG. 6 is a cross-sectional view taken along a B-B direction in FIG. 3.

The imaging apparatus 101 depicted in FIGS. 5 and 6 includes the semiconductor substrate 11, the photoelectric converting section 51, the charge holding section MEM, the transfer transistors TRZ, TRY, TRX, and TRG, the discharge transistor OFG, the floating diffusion FD, the first light shielding section 12, a second light shielding section 13, element isolating sections 13V and 20, a wiring layer 80, a fixed charge film 15, a color filter CF, and a light receiving lens LNS. The transfer transistors TRZ includes the vertical gate electrode VG which is a vertical electrode.

In the imaging apparatus 100 of the present embodiment, a silicon substrate is used as the semiconductor substrate 11. Signs “P” and “N” in the figures respectively represent a P type semiconductor region and an N type semiconductor region. Further, “+” or “−” at the end of each of the signs “P++,” “P+,” “P−,” and “P−−” represents the concentration of impurities in the P type semiconductor region. Similarly, “+” or “−” at the end of each of the signs “N++,” “N+,” “N−,” and “N−−” represents the concentration of impurities in the N type semiconductor region. Here, a larger number of “+” indicates a higher concentration of impurities, and a larger number of “−” indicates a lower concentration of impurities. This also applies to the subsequent drawings.

In the specification, one principal surface on the side of the semiconductor substrate 11 where the wiring layer 80 and the readout circuit 120 are disposed is referred to as a first surface 11A, and one principal surface on the side of the semiconductor substrate 11 where the light receiving lens LNS is disposed is referred to as a second surface 11B or a light receiving surface. The first surface 11A is a surface of the semiconductor substrate 11 opposite to a light incident surface. The second surface 11B is the light incident surface of the semiconductor substrate 11. Further, in the specification, the first surface 11A may be referred to as a “front surface,” and the second surface 11B may be referred to as a “back surface.”

The photoelectric converting section 51 in the semiconductor substrate 11 includes, for example, an N− type semiconductor region 51A, an N type semiconductor region 51B, and a P type semiconductor region 51C in the order of being close to the second surface 11B.

Light incident on the second surface 11B is photoelectrically converted in the N− type semiconductor region 51A to generate charge, which is accumulated in the N type semiconductor region 51B. Note that the boundary between the N− type semiconductor region 51A and the N type semiconductor region 51B is not necessarily clear and that, for example, the concentration of N type impurities is only required to be gradually increased from the N− type semiconductor region 51A toward the N type semiconductor region 51B. Further, between the N type semiconductor region and the P type semiconductor region 51C, a P+ type semiconductor region that has a higher P type impurity concentration than the P type semiconductor region 51C may be provided. In such a manner, the layer configuration of the photoelectric converting section 51 formed in the semiconductor substrate 11 is not necessarily limited to the layer configuration depicted in FIGS. 5 and 6.

The charge holding section MEM is configured as an N+ type semiconductor region provided in the P type semiconductor region 51C.

The transfer transistor TRZ includes a horizontal gate electrode HG disposed in a horizontal plane direction of the semiconductor substrate 11 and the vertical gate electrode VG extending in a depth direction of the semiconductor substrate 11. The deepest position of the vertical gate electrode VG is, for example, in the N− type semiconductor region 52A. In the example illustrated in FIG. 5, each sensor pixel 121 includes two vertical gate electrodes VG. However, the number of vertical gate electrodes VG is not limited to any number, and may be one or more. The transfer transistor TRZ transfers charge resulting from photoelectric conversion in the photoelectric converting section 51, to the transfer electrode TRY via the vertical gate electrode VG.

The gate electrodes of the transfer transistors TRZ, TRY, TRX, and TRG and the discharge transistor OFG are provided on the first surface 11A side of the semiconductor substrate 11 via an insulating layer 18.

The floating diffusion FD is configured as an N++ type semiconductor region provided in the P type semiconductor region 51C.

The wiring layer 80 is a layer in which peripheral circuits for the readout circuit 120 and the imaging apparatus 101 are disposed.

The first light shielding section 12 is a member producing a light shielding effect and functioning to prevent light from the second surface 11B side from entering the charge holding section MEM. The first light shielding section 12 is excellent in optical absorption property or reflection property.

The first light shielding section 12 is disposed between the photoelectric converting section 51 and the charge holding section MEM, surrounding at least a part of the charge holding section MEM. Specifically, the first light shielding section 12 includes a horizontal light shielding portion 12H spreading in an in-plane direction of the semiconductor substrate 11 between the photoelectric converting section 51 and the charge holding section MEM and a vertical light shielding portion 12V shaped like a wall that is extending from the first surface 11A of the semiconductor substrate 11 in the depth direction and that is connected to the horizontal light shielding portion 12H. In the illustrated example, the horizontal light shielding portion 12H spreads in the in-plane direction of an XY plane, and the vertical light shielding portion 12V spreads in the in-plane direction of a YZ plane.

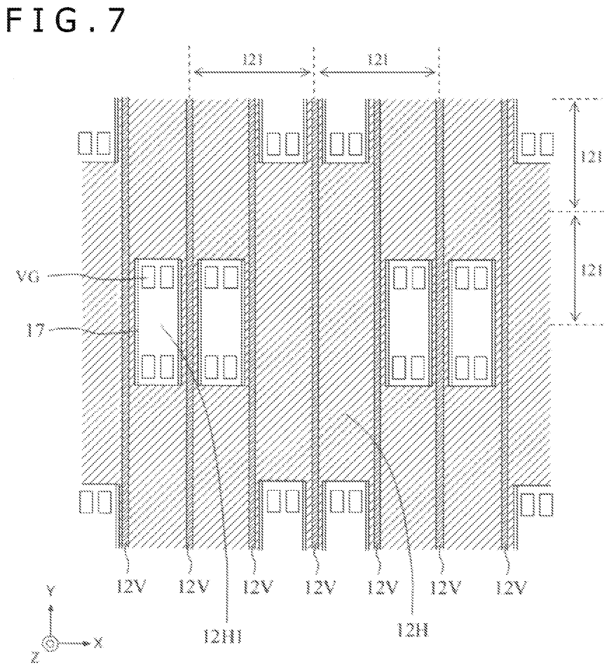

FIG. 7 is a horizontal cross-sectional view illustrating the arrangement of the first light shielding section 12 and depicting a C-C cross section in FIG. 6.

As depicted in FIGS. 6 and 7, the vertical light shielding portion 12V of the first light shielding section 12 extends, in plan view, in the Y axis direction along the boundary portion between the sensor pixels 121 adjacent to each other in the X axis direction and along a substantially central portion of the sensor pixel 121. The vertical light shielding portion 12V extends from the first surface 11A of the semiconductor substrate 11 in the depth direction and connects to the horizontal light shielding portion 12H. The vertical light shielding portions 12V are arranged at approximately half-pixel intervals in the X axis direction and have a length corresponding to a plurality of pixels in the Y axis direction.

As depicted in FIGS. 5 to 7, the horizontal light shielding portion 12H of the first light shielding section 12 spreads from the deepest position of the vertical light shielding portion 12V of the first light shielding section 12 in a transverse (horizontal) direction. In FIG. 7, a hatched region is the horizontal light shielding portion 12H. In the horizontal light shielding portions 12H, openings 12H1 are provided in places.

The opening 12H1 is provided with an etching stopper 17. As described below, the horizontal light shielding portion 12H is formed by forming a trench in the depth direction and the horizontal direction by wet etching treatment and filling the inside of the trench with a light shielding material, and provision of the etching stopper 17 makes it possible to stop progression of etching, leading to formation of the opening 12H1 as depicted in FIG. 7.

As depicted in FIGS. 5 and 6, the horizontal light shielding portion 12H of the first light shielding section 12 is positioned between the photoelectric converting section 51 and the charge holding section MEM in the depth (Z axis) direction. As depicted in FIG. 7, the horizontal light shielding portion 12H is provided across the entire XY plane of the pixel array section 111 except for the openings 12H1.

In a case where the horizontal light shielding portion 12H of the first light shielding section 12 has a function to reflect light, light enters the second surface 11B and is transmitted through the photoelectric converting section 51 without being absorbed by the photoelectric converting section 51, and the light is reflected from the horizontal light shielding portion 12H of the first light shielding section 12, and enters the photoelectric converting section 51 again, contributing to photoelectric conversion. That is, the horizontal light shielding portion 12H of the first light shielding section 12 functions as a reflector and restricts light transmitted through the photoelectric converting section 51 from entering the charge holding section MEM to cause noise, and functions to improve a photoelectric conversion efficiency Qe and enhance sensitivity.

Further, the vertical light shielding portion 12V of the first light shielding section 12 functions to prevent leaking light from the adjacent sensor pixel 121 from entering the photoelectric converting section 51 to cause noise such as color mixture.

As depicted in FIGS. 6 and 7, the vertical light shielding portions 12V of the first light shielding sections 12 are provided at half-pixel intervals along the X axis direction, extending in the Y axis direction. The charge holding section MEM is disposed between two vertical light shielding portions 12V adjacent to each other in the X direction. Further, the horizontal light shielding portion 12H of the first light shielding section 12 is disposed between the charge holding section MEM and the photoelectric converting section 51, and the charge holding section MEM is surrounded by the vertical light shielding portion 12V and the horizontal light shielding portion 12H. This prevents light having failed to be photoelectrically converted in the photoelectric converting section 51 from entering the charge holding section MEM, enabling a reduction in noise. The first light shielding section 12 is electrically connected to a wiring section provided on the first surface 11A side of the semiconductor substrate 11.

As depicted in FIGS. 5 and 6, the first light shielding section 12 has a two-layer structure of a light shielding material section 12A and an insulating film 12B covering the periphery of the light shielding material section 12A.

The light shielding material section 12A includes, for example, a material containing at least one type of single-component metal, metal alloy, metal nitride, and metal silicide that produces a light shielding effect. More specifically, an example of a material constituting the light shielding material section 12A includes W (tungsten), Ti (titanium), Ta (tantalum), Ni (nickel), Mo (molybdenum), Cr (chromium), Ir (iridium), platina iridium, TiN (titanium nitride), Al (aluminum), Cu (copper), Co (cobalt), a tungsten silicon compound, or the like. Note that the material constituting the light shielding material section 12A is not limited to the materials listed above. For example, a material other than metal that produces a light shielding effect may be used.

The insulating film 12B includes an insulating material, for example, SiOx (silicon oxide) or the like. The insulating film 12B ensures electrical insulation between the light shielding material section 12A and the semiconductor substrate 11.

The second light shielding section 13 is a member producing a light shielding effect and functioning to prevent light incident from the second surface 11B side of the semiconductor substrate 11 from entering the vertical gate electrode VG and the like. The second light shielding section 13 is excellent in optical absorption property or reflection property.

The second light shielding section 13 is disposed closer to the second surface 11B of the semiconductor substrate 11 than the first light shielding section 12. The second light shielding section 13 includes a vertical light shielding portion 13V extending in the depth direction of the semiconductor substrate 11 and a horizontal light shielding portion 13H extending in the horizontal direction of the semiconductor substrate 11. The vertical light shielding portion 13V also serves as a part of the element isolating sections 13V and 20 described below. As depicted in FIG. 5, a cross section of the second light shielding section 13 has a T shape formed by the vertical light shielding portion 13V and the horizontal light shielding portion 13H.

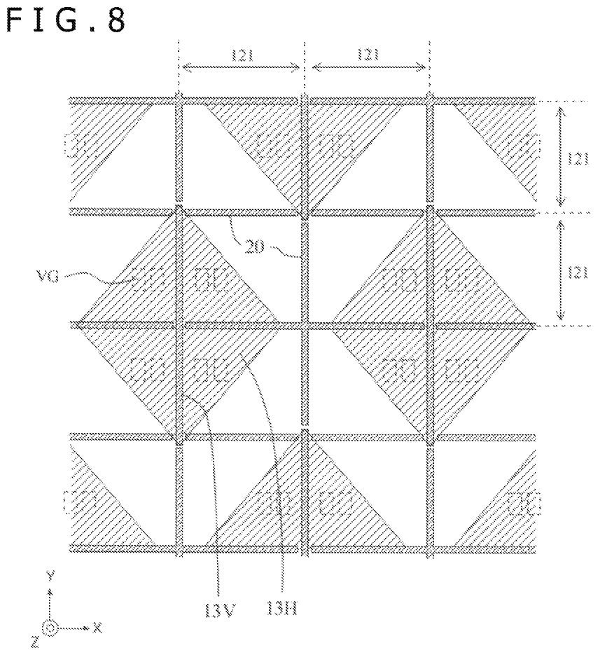

FIG. 8 is a transverse cross-sectional view illustrating the arrangement of the second light shielding section 13 and the element isolating sections 13V and 20 and depicting a D-D cross section in FIG. 6.

As depicted in FIG. 8, the second light shielding sections 13 are arranged in a zigzag shape along the boundaries between the sensor pixels 121 in the XY plane. The horizontal light shielding portion 13H of the second light shielding section 13 extending horizontally from the vertical light shielding portion 13V is shaped like, for example, a rhombus along the crystal face of the silicon substrate 11. In plan view, the horizontal light shielding portion 13H is disposed at a position different from the vertical gate electrode VG of the transfer transistor TRZ in the depth direction. Thus, the horizontal light shielding portion 13H shields the vertical gate electrode VG from light incident from the second surface 11B side of the semiconductor substrate 11.

As depicted in FIGS. 5 and 6, similarly to the first light shielding section 12, the second light shielding section 13 has a two-layer structure of a light shielding material section 13A and an insulating film 13B covering the periphery of the light shielding material section 13A.

The element isolating sections 13V and 20 are provided along the boundaries between the pixels and include a first element isolating section 13V and a second element isolating section 20. The first element isolating section 13V corresponds to the vertical light shielding portion 13V of the second light shielding section 13 described above.

The second element isolating section 20 is a member shaped like a wall extending along the boundary position between the adjacent sensor pixels 121 in the depth (Z axis) direction and surrounding each photoelectric converting section 51. The second element isolating section 20 allows the adjacent sensor pixels 121 to be electrically separated from each other. The second element isolating section 20 includes an insulating material, for example, silicon oxide or the like. The second element isolating section 20 can be used to prevent light from entering the adjacent sensor pixel 121. The second element isolating section 20 includes a material excellent in optical absorption property or reflection property.

As depicted in FIG. 8, the element isolating sections 13V and 20 are disposed along the boundaries between the sensor pixels 121, surrounding side surfaces of the photoelectric converting section 51 of each sensor pixel 121.

As depicted in FIGS. 5, 6, and 8, the first element isolating section (the vertical light shielding portion of the second light shielding section 13) 13V or the second element isolating section 20 is disposed at the boundary between the sensor pixels 121. In FIGS. 5 and 6, the second element isolating section 20 includes only the vertical light shielding portion, but may include the vertical light shielding portion and the horizontal light shielding portion. The cross section of the second element isolating section 20 may have any of various shapes such as a T shape and a cross shape.

Both the first element isolating section (the vertical light shielding portion of the second light shielding section 13) 13V and the second element isolating section 20 can prevent light entering each sensor pixel 121 from the second surface 11B of the semiconductor substrate 11 from leaking to the adjacent sensor pixel 121, enabling a reduction in crosstalk between the pixels.

As depicted in FIGS. 5 and 6, similarly to the first light shielding section 12 and the second light shielding section 13, the second element isolating section 20 has a two-layer structure of a light shielding material section 20A and an insulating film 20B covering the periphery of the light shielding material section 20A.

The first light shielding section 12, the second light shielding section 13, and the second element isolating section 20 do not necessarily have the same structure and include the same material but have a common feature of containing a material excellent in optical absorption property or reflection property. The first light shielding section 12 includes the vertical light shielding portion extending from the first surface 11A of the semiconductor substrate 11 in the depth direction, whereas the second light shielding section 13 and the second element isolating section 20 include the vertical light shielding portion extending from the second surface 11B side of the semiconductor substrate 11 in the depth direction.

As depicted in FIGS. 5 and 6, the fixed charge film 15 is provided between the photoelectric converting section 51 and the second surface 11B. The fixed charge film 15 is provided along the second surface 11B of the semiconductor substrate 11. The fixed charge film 15 has negative fixed charge to suppress a possible dark current caused by an interface state of the second surface 11B of the semiconductor substrate 11, which is a light receiving surface. An electric field induced by the fixed charge film 15 forms a hole accumulation layer near the second surface 11B of the semiconductor substrate 11. The hole accumulation layer suppresses generation of electrons from the second surface 11B.

As depicted in FIGS. 5 and 6, the color filter CF is disposed below the fixed charge film 15 (−Z direction), and the light receiving lens LNS is disposed below the color filter CF (−Z direction). The color filter CF and the light receiving lens LNS are provided on a pixel by pixel basis.

### (Electrically Conductive Section 12C of First Light Shielding Section 12)

In the imaging apparatus configured as described above, the disclosers of the present disclosure have found out, as a result of studies, that the first light shielding section 12 causes defects during the manufacturing steps for the imaging apparatus 101 for the following reasons.

In the first light shielding section 12, the light shielding material section 12A is covered with the insulating film 12B. Thus, in a case where the light shielding material section 12A of the first light shielding section 12 includes a conductive material, the light shielding material section 12A is in a floating state inside the semiconductor substrate 11. Accordingly, there is a risk that plasma induces arcing (abnormal discharge) during processing such as dry etching in the manufacturing steps after formation of the first light shielding section 12 on the semiconductor substrate 11. In the imaging apparatus 101, the arcing causes such defects as lattice defects in the semiconductor substrate 11.

Further, the disclosers of the present disclosure have found out that possible arcing during the manufacturing steps for the imaging apparatus 101, that is, possible defects, can be suppressed by allowing a partial region of the first light shielding section 12 to be electrically conductive with the semiconductor substrate 11 to fix the potential of the first light shielding section 12. Thus, the imaging apparatus 101 of the present embodiment has the feature that the first light shielding section 12 is electrically conductive with the semiconductor substrate at the partial region.

FIG. 9 is a plane layout diagram depicting the region of the electrically conductive section 12C of the first light shielding section 12. FIG. 10 is a longitudinal cross-sectional view illustrating the cross-section structure of a region outside an effective pixel region 111A of the imaging apparatus 101 and depicting an E-E cross section in FIG. 9.

As depicted in FIG. 10, the first light shielding section 12 includes the light shielding material section 12A including a conductive light shielding material and the insulating film 12B covering the periphery of the light shielding material section 12A, and includes, at a partial region, the electrically conductive section 12C at which the light shielding material section 12A connects to the semiconductor substrate 11 without intervention of the insulating film 12B. In the illustrated example, the electrically conductive section 12C of the first light shielding section 12 is provided on a bottom surface of the vertical light shielding portion 12V.

In the example illustrated in FIGS. 9 and 10, the first light shielding section 12 is electrically conductive with the semiconductor substrate 11 at a part of the region outside the effective pixel region 111A of the imaging apparatus 101. In other words, the first light shielding section 12 does not include the electrically conductive section 12C in a region inside the effective pixel region 111A and includes the electrically conductive section 12C in the region outside the effective pixel region 111A.

Here, the effective pixel region 111A means a region in which the sensor pixels 121 used for imaging by the imaging apparatus 101 are disposed. Typically, the pixel sensors 121 near peripheral edges of the pixel array section 111 are not used for imaging by the imaging apparatus 101. For example, the effective pixel region 111A is a region extending a certain number of pixels, for example, 20 pixels, inward from an end of the pixel array section 111.

The first light shielding section 12 does not include the electrically conductive section 12C in the region inside the effective pixel region 111A in terms of suppression of a dark current or the effect of a negative bias applied to the first light shielding section 12. In a case where the electrically conductive section 12C is present inside the effective pixel region 111A, results of imaging in the imaging apparatus 101 are unfavorably affected by a change in an energy profile or a crystal state at the periphery of the electrically conductive section 12C.

A sequence of the horizontal light shielding portions 12H of the first light shielding section 12 is arranged from the inside of the effective pixel region 111A toward the outside of the effective pixel region 111A. Accordingly, even in a case where the first light shielding section 12 includes the electrically conductive section 12C only in the region outside the effective pixel region 111A, the potential of the first light shielding section 12 is fixed.

Further, the first light shielding section 12 includes the electrically conductive section 12C in the inside region spaced from the first surface 11A and the second surface 11B rather than on the first surface 11A or the second surface 11B of the semiconductor substrate 11 in terms of reserving an area on the semiconductor substrate 11, reducing the number of manufacturing steps, a polishing step that is to be performed after formation of the first light shielding section 12, and the like.

Further, in the example illustrated in FIGS. 9 and 10, the electrically conductive section 12C is provided not on the bottom surfaces of all the vertical light shielding portions 12V arranged in the X direction but on the bottom surfaces of some of the vertical light shielding portions 12V. In the illustrated example, the vertical light shielding portions 12V provided with the electrically conductive section 12C are disposed alternately with the vertical light shielding portions 12V not provided with the electrically conductive section 12C.

The region of the electrically conductive section 12C is preferably as large as possible in view of maintenance of electrical conductivity between the first light shielding section 12 and the semiconductor substrate 11. However, a larger region of the electrically conductive section 12C increases the risk that the semiconductor substrate 11 or the like is damaged during etching or the like in a forming step for the electrically conductive section 12C described below. Thus, in this regard, the region of the electrically conductive section 12C is preferably as small as possible. Accordingly, in the illustrated example, the electrically conductive section 12C is provided in a part of the region outside the effective pixel region 111A.

In conclusion, the imaging apparatus 101 of the present embodiment includes the photoelectric converting section 51 disposed on the semiconductor substrate 11, the charge holding section MEM disposed on the side of the photoelectric converting section 51 corresponding to the first surface 11A of the semiconductor substrate 11, and the first light shielding section 12 that is disposed between the photoelectric converting section 51 and the charge holding section MEM and that covers at least a part of the charge holding section MEM. The first light shielding section 12 includes the electrically conductive section 12C that is a partial region of the first light shielding section 12 and that is electrically conductive with the semiconductor substrate 11.

The imaging apparatus 101 as described above is configured to suppress the risk of possible arcing during the manufacturing steps and hence to suppress possible defects.

### 2. Manufacturing Method for Imaging Apparatus of Present Embodiment

Now, an example of a manufacturing method for the imaging apparatus 101 will be described.

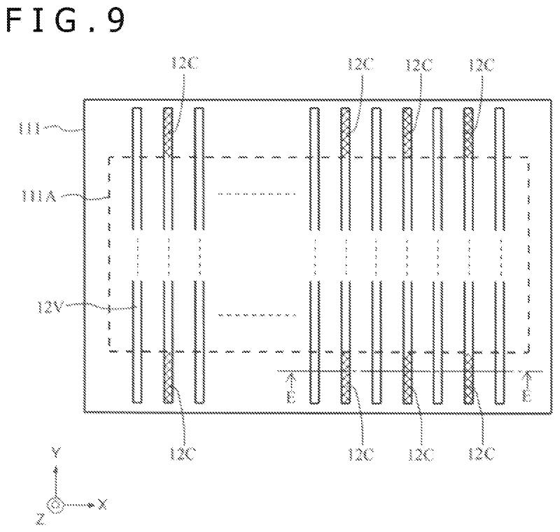

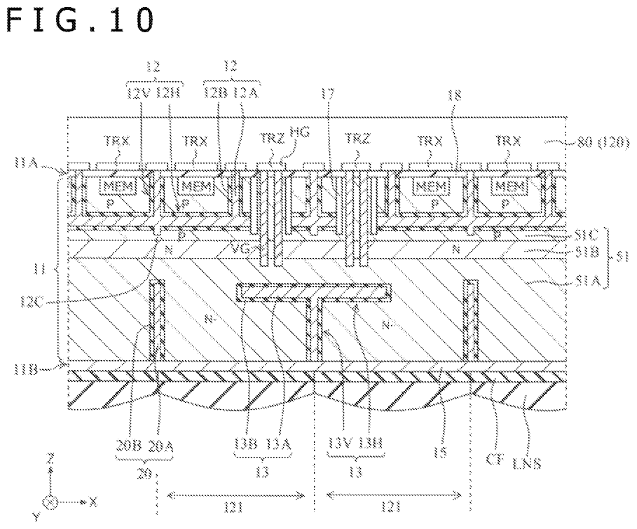

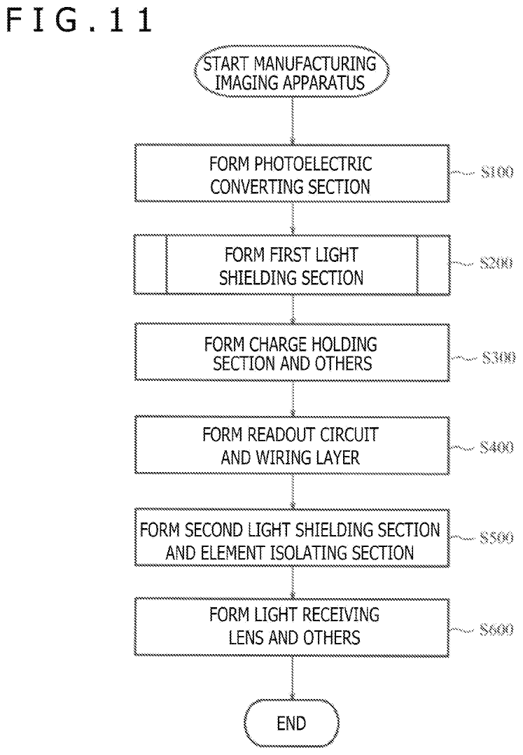

FIG. 11 is a flow diagram illustrating an example of the manufacturing method for the imaging apparatus 101 of the present embodiment.

The manufacturing method for the imaging apparatus 101 of the present embodiment includes step S100 of forming the photoelectric converting section 51 on the semiconductor substrate 11, step S200 of forming the first light shielding section 12, step S300 of forming the charge holding section MEM and the like, step S400 of forming the readout circuit 120 and the wiring layer 80, step S500 of forming the second light shielding section 13 and the element isolating sections 13V and 20, and step S600 of forming the light receiving lens LNS and the like.

A specific example of the manufacturing method for the imaging apparatus 101 will be described below.

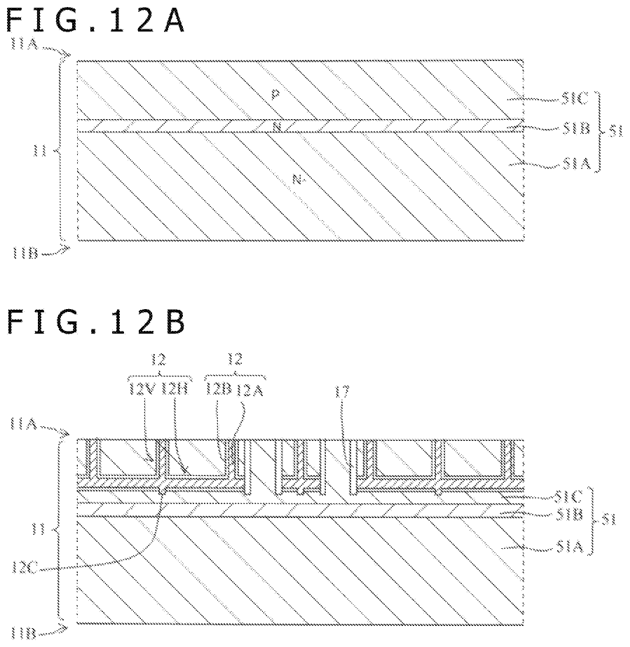

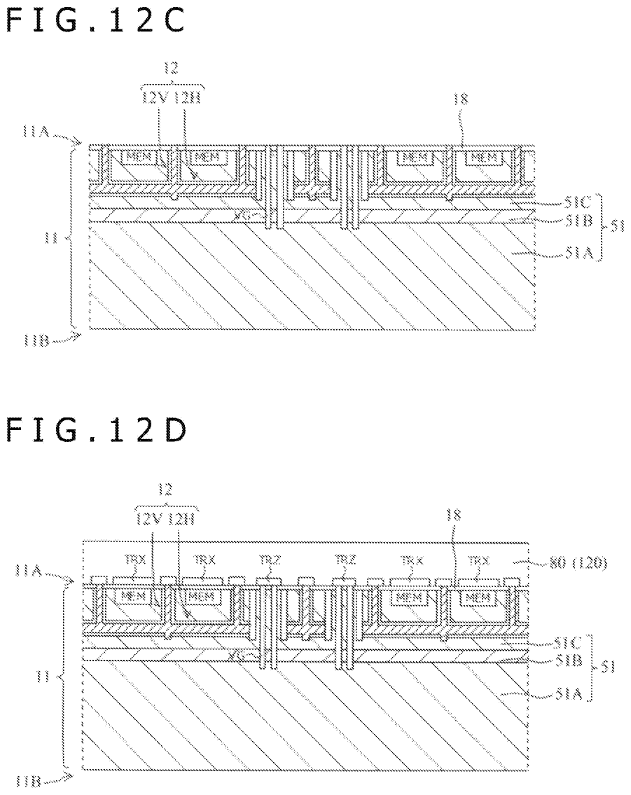

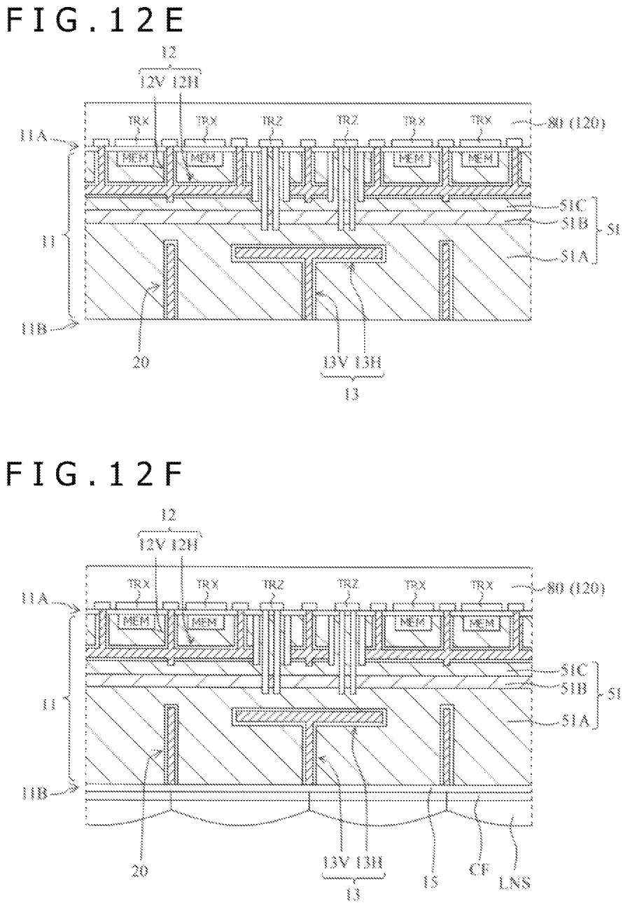

FIGS. 12A to 12F are longitudinal cross-sectional views illustrating an example of the manufacturing method for the imaging apparatus 101.

First, as depicted in FIG. 12A, the photoelectric converting section 51 is formed on the semiconductor substrate 11 (S100). In the illustrated example, a silicon substrate 11 of a single crystal having a crystal orientation of a plane index {111} is used as the semiconductor substrate 11. Further, in the illustrated example, the photoelectric converting section 51 has a structure including the N− type semiconductor region 51A, the N type semiconductor region 51B, and the P type semiconductor region 51C laminated together.

Next, as depicted in FIG. 12B, the first light shielding section 12 is formed on the side of the photoelectric converting section 51 corresponding to the first surface 11A of the semiconductor substrate 11 (S200). The first light shielding section 12 includes the light shielding material section 12A containing a conductive light shielding material, and the insulating film 12B covering the periphery of the light shielding material section 12A. Further, the first light shielding section 12 is provided, at a partial region thereof, with the electrically conductive section 12C at which the light shielding material section 12A connects to the semiconductor substrate 11 without intervention of the insulating film 12B. Step S200 of forming the light shielding section 12 will be described below in detail.

Subsequently, as depicted in FIG. 12C, the charge holding section MEM is formed on the side of the first light shielding section 12 corresponding to the first surface 11A of the semiconductor substrate 11 (S300). At this time, the floating diffusion FD and the vertical gate electrode VG of the transfer transistor TRZ, for example, are also formed. The charge holding section MEM and the floating diffusion FD are formed by, for example, injecting N type ions into the semiconductor substrate 11. Further, the vertical gate electrode VG is formed by, for example, forming a trench by dry etching using a hard mask, and filling the inside of the trench with polysilicon.

Then, as depicted in FIG. 12D, the readout circuit 120 and the wiring layer 80 are formed on the first surface 11A side of the semiconductor substrate 11 (S400).

Subsequently, as depicted in FIG. 12E, the second light shielding section 13 and the element isolating sections 13V, 20 are formed on the second surface 11B of the semiconductor substrate 11 (S500). Step S500 of forming the second light shielding section 13 and the element isolating sections 13V and 20 will be described below in detail.

Finally, as depicted in FIG. 12F, the fixed charge film 15, the color filter CF, and the light receiving lens LNS are sequentially formed on the second surface 11B of the semiconductor substrate 11.

The manufacturing method for the imaging apparatus 101 described above includes the step using plasma, such as dry etching, after forming the first light shielding section 12. In this regard, in the manufacturing method for the imaging apparatus 101 of the present embodiment, the first light shielding section 12 is provided with the electrically conductive section 12C that is electrically conductive with the semiconductor substrate 11. Thus, in the step using plasma, such as dry etching, the risk of possible arcing is suppressed.

### (Step S200 of Forming First Light Shielding Section 12)

Now, step 200 of forming the first light shielding section 12 will be described in detail.

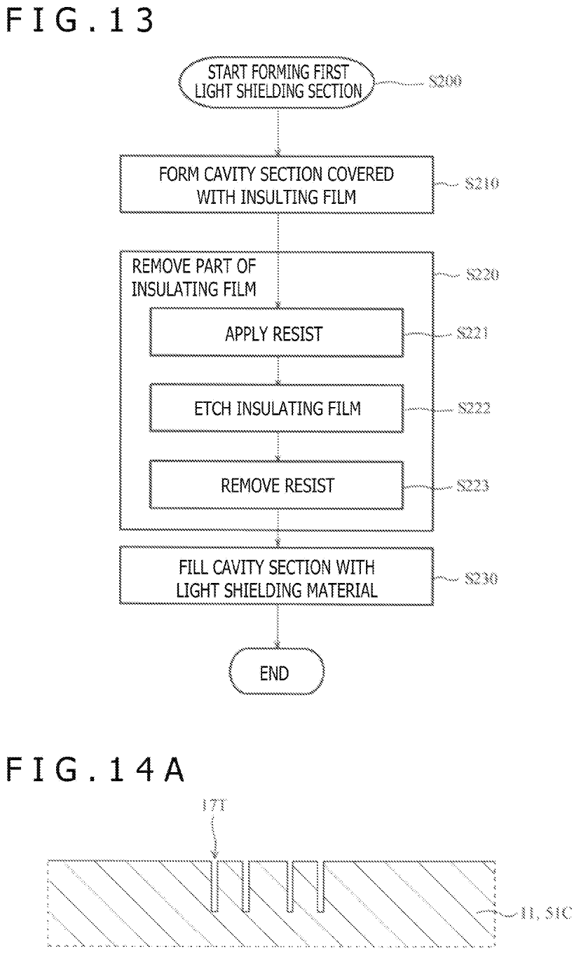

FIG. 13 is a flow diagram illustrating an example of step S200 of forming the first light shielding section 12.

Step S200 of forming the first light shielding section 12 includes step S210 of forming a cavity section 12E covered with the insulating film 12B, step 220 of removing a part of the insulating film 12B, and step S230 of filling the cavity section 12E with a light shielding material. Further, step S220 of removing a part of the insulating film 12B includes step S221 of applying resist 60, step S222 of etching the insulating film 12B, and step 223 of removing the resist 60.

(Step S210 of Forming Cavity Section 12E Covered with Insulating Film 12B)

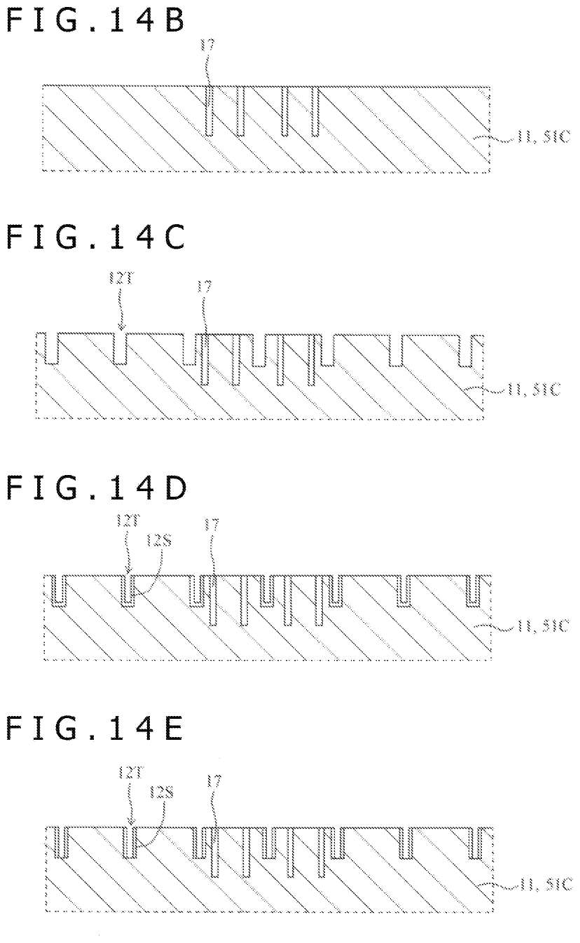

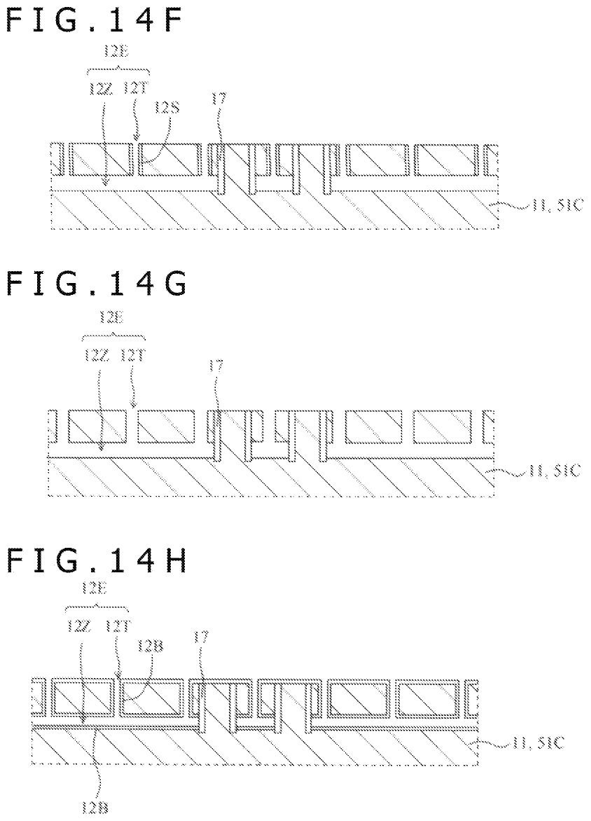

FIGS. 14A to 14H are longitudinal cross-sectional views illustrating an example of step S210 of forming the cavity section 12E covered with the insulating film 12B. With reference to FIGS. 14A to 14H, a specific example of this step will be described.

First, as depicted in FIG. 14A, on the semiconductor substrate 11 provided with the photoelectric converting section 51, a trench 17T is formed in such a manner as to be aligned with the position of the etching stopper 17 used in forming the horizontal light shielding portion 12H of the first light shielding section 12. The trench 17T is provided by, for example, dry etching using a hard mask. The hard mask includes an insulating material such as SiN (silicon nitride) or SiO₂ (silicon oxide).

Next, as depicted in FIG. 14B, the inside of the trench 17T is filled with, for example, an insulator such as a crystal defect structure doped with impurity elements such as B (boron) or hydrogen ions, or an oxide, to form the etching stopper 17.

Subsequently, as depicted in FIG. 14C, dry etching using a hard mask, or the like is performed to form a trench 12T aligned with the position of the vertical light shielding portion 12V of the first light shielding section 12.

Then, as depicted in FIG. 14D, a sidewall 12S is formed in such a manner as to cover side surfaces and a bottom surface of the trench 12T. The sidewall 12S is formed using an insulating film including, for example, SiN, SiO₂, or the like.

Subsequently, as depicted in FIG. 14E, for example, dry etching is used to remove the sidewall 12S from the bottom surface of the trench 12T, while the sidewall 12S is left on the side surface portions of the trench 12T.

Then, as depicted in FIG. 14F, a predetermined alkali aqueous solution is injected into the trench 12T to subject the trench 12T to wet etching, thus removing a part of the semiconductor substrate 11. Examples of an applicable alkali aqueous solution include an inorganic solution, such as KOH, NaOH, or CsOH, and an organic solution, such as EDP (ethylenediamine pyrocatechol aqueous solution), N2H4 (hydrazine), NH4OH (ammonium hydroxide), or TMAH (tetramethylammonium hydroxide).

Here, crystal anisotropic etching is performed utilizing the property that an etching rate varies depending on the plane orientation of the silicon substrate 11. Specifically, in the silicon substrate 11 having a crystal orientation of the plane index {111}, the etching rate in a <110> direction is sufficiently higher than the etching rate in a <111> direction. Accordingly, in the present embodiment, etching progresses in the X axis direction, whereas etching progresses very little in the Y axis direction and the Z axis direction. As a result, a horizontal cavity portion 12Z that is in communication with the trench 12T is formed inside the semiconductor substrate 11, which is the silicon substrate 11 having a crystal orientation of the plane index {111}.

Note that the distance etching progresses in the <110> direction can be adjusted by the time of etching treatment for the semiconductor substrate 11 that uses an alkali aqueous solution. Yet, by pre-providing the etching stopper 17 at a predetermined position as in the present embodiment, the progress of etching in the <110> direction can easily be controlled. The etching stopper 17 stops the progress of etching in the <110> direction (see FIG. 7).

Next, as depicted in FIG. 14G, the sidewall 12S is removed by, for example, wet etching. Note that the sidewall 12S may be removed by isotropic dry etching. For wet etching, in a case where the sidewall 12S includes SiO₂, a liquid medicine containing HF (hydrofluoric acid), for example, DHF (dilute hydrofluoric acid) or BHF (buffered hydrofluoric acid) is desirably used. Alternatively, in a case where the sidewall 12S includes SiN, a liquid medicine containing hot phosphoric acid or HF is desirably used. Note that the sidewall 12S need not necessarily be removed.

Finally, as depicted in FIG. 14H, the insulating film 12B is formed in such a manner as to cover the side surfaces of the trench 12T, the inner surface of the horizontal cavity portion 12Z, and the first surface 11A of the semiconductor substrate 11. The insulating film 12B is formed by, for example, depositing SiO₂ (silicon oxide) with use of an Atomic Layer Deposition method.

Note that the cavity section 12E and the insulating film 12B can be formed using any of various known semiconductor process technologies instead of the above-described method. For example, the cavity section 12E can also be formed by forming a sacrifice layer in the semiconductor substrate 11 and selectively removing the sacrifice layer by etching. Further, the insulating film 12B can also be formed using a chemical vapor deposition method or thermal oxidation method. In the manufacture of the imaging apparatus 101 according to the present disclosure, forming methods for the cavity section 12E and the insulating film 12B are not limited to the above-described methods, and may be any methods using any other semiconductor process technology.

### (Step S220 of Removing Part of Insulating Film 12B)

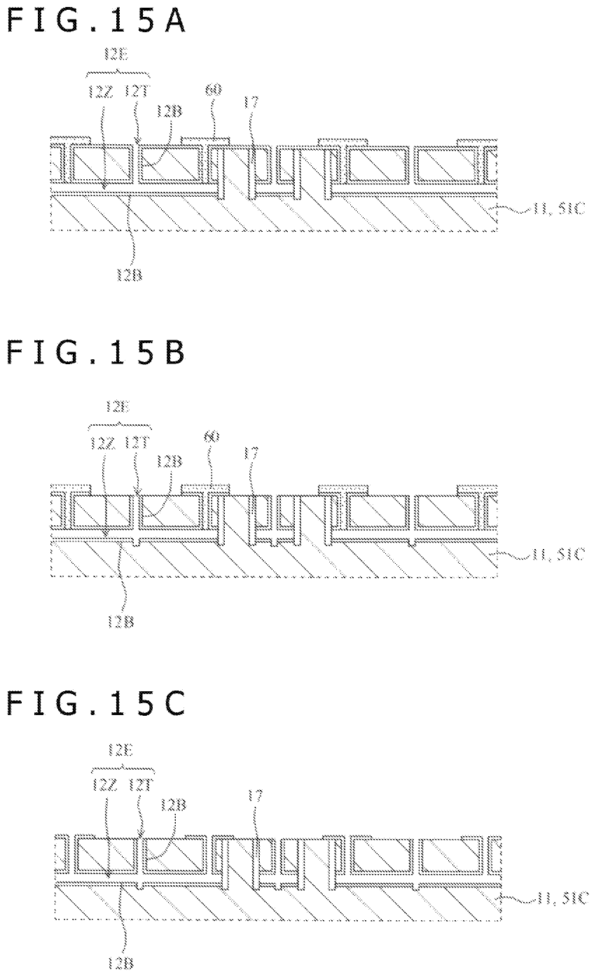

FIGS. 15A to 15C are longitudinal cross-sectional views illustrating an example of step S220 of removing a part of the insulating film 12B. With reference to FIGS. 15A to 15C, a specific example of this step will be described.

First, as depicted in FIG. 15A, the resist 60 is applied onto a portion of the insulating film 12B that is to be left in this step instead of being removed. No resist 60 is applied onto the portion of the insulating film 12B that is to be removed in this step.

FIG. 16 is a plane layout diagram depicting a region to which the resist 60 is applied. In the example illustrated in FIG. 16, the region to which the resist 60 is applied includes the entire effective pixel region 111A of the imaging apparatus 101. Further, the region to which the resist 60 is applied includes a part of the region outside the effective pixel region 111A.

Next, as depicted in FIG. 15B, anisotropic etching is performed from the upper side of the semiconductor substrate 11 to remove the insulating film 12B on the bottom surface of the trench 12T in the region to which no resist 60 is applied. The anisotropic etching is performed by, for example, reactive ion etching.

In a case where the insulating film 12B is removed by anisotropic etching as described above, the resist 60 need not be embedded in the horizontal cavity portion 12Z of the cavity section 12E, and is only required to be applied in such a manner as to cover at least the opening of the trench 12T.

Finally, as depicted in FIG. 15C, the resist 60 applied onto the semiconductor substrate 11 is removed.

(Step S230 of Filling Cavity Section 12E with Light Shielding Material)

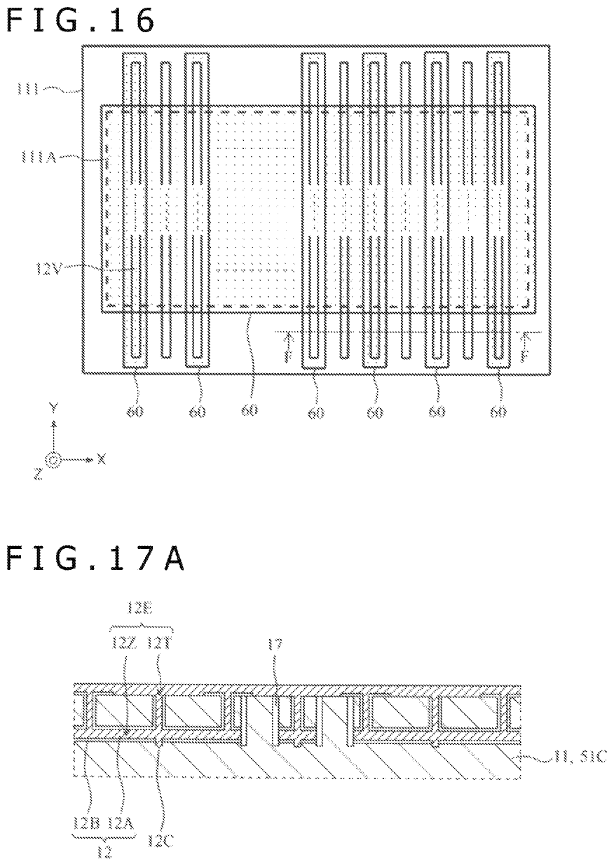

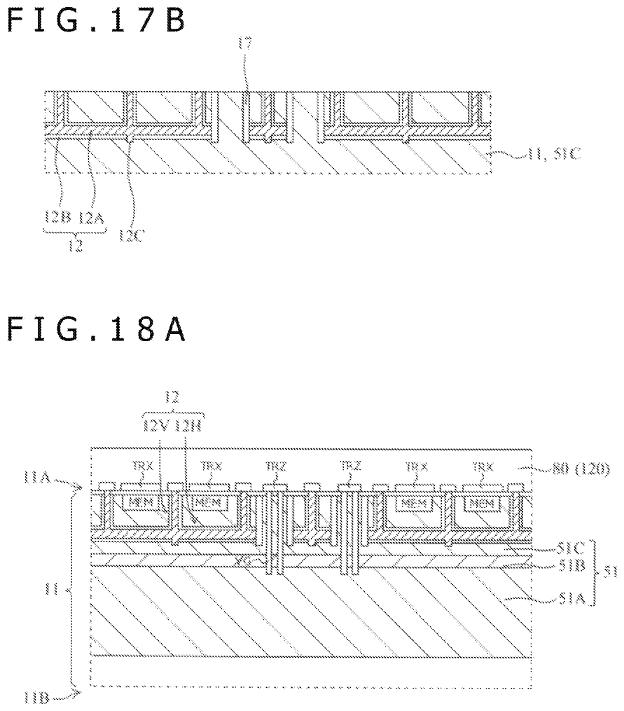

FIGS. 17A and 17B are longitudinal cross-sectional view illustrating an example of step S230 of filing the cavity section 12E with the light shielding material. With reference to FIGS. 17A and 17B, a specific example of this step will be described.

First, as depicted in FIG. 17A, the light shielding material constituting the light shielding material section 12A is embedded inside the cavity section 12E. The light shielding material is embedded in the cavity section 12E with use of, for example, the chemical vapor deposition method.

Finally, as depicted in FIG. 17B, the front surface of the semiconductor substrate 11 is polished and planarized by, for example, CMP (Chemical Mechanical Polishing) to remove the light shielding material and the insulating film 12B on the front surface of the semiconductor substrate 11.

### (Step S500 of Forming Second Light Shielding Section 13 and Element Isolating Sections 13V and 20)

Step S500 of forming the second light shielding section 13 and the element isolating sections 13V and 20 will be described below in detail.

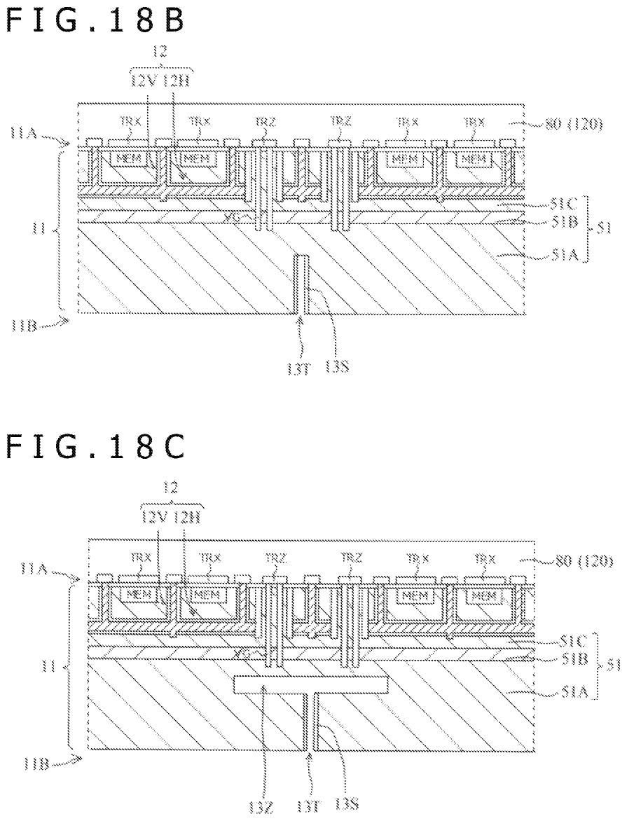

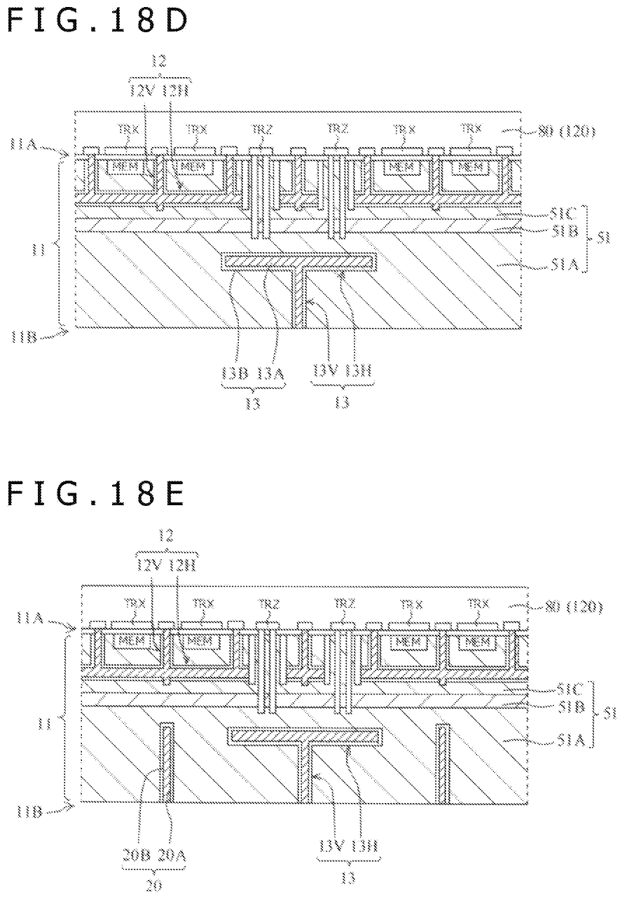

FIGS. 18A to 18E are longitudinal cross-sectional views illustrating an example of step S500 of forming the second light shielding section 13 and the element isolating sections 13V and 20. With reference to FIGS. 18A and 18B, a specific example of this step will be described.

First, as depicted in FIG. 18A, the second surface 11B side of the semiconductor substrate 11 is thinned by CMP (Chemical Mechanical Polishing) or the like.

Next, as depicted in FIG. 18B, a trench 13T covered with a sidewall 13S only at the side surfaces of the trench 13T is formed on the second surface 11B of the semiconductor substrate 11 as in the step of forming the first light shielding section 12 (see FIGS. 14A to 14E).

Subsequently, as depicted in FIG. 18C, a predetermined alkali aqueous solution is injected into the trench 13T to subject the trench 13T to anisotropic etching, as in the step of forming the first light shielding section 12 (see FIG. 14F), forming a horizontal cavity portion 13Z spreading in the horizontal direction. The anisotropic etching shapes the horizontal cavity portion 13Z like, for example, a rhombus as depicted in FIG. 8, as seen in plan view.

Then, as depicted in FIG. 18D, the second light shielding section 13 is formed by sequentially performing removal of the sidewall 13S, formation of the insulating film 13B, and formation of the light shielding material section 13A by filling with the light shielding material, as in the step of forming the first light shielding section 12 (see FIGS. 14G, 14H, 14L, and 14M).

Finally, as depicted in FIG. 18E, the element isolating section 20 is formed along the boundary portion between the pixels. The element isolating section 20 is formed by, for example, sequentially performing formation of a trench, formation of the insulating film 20B covering the side surfaces and bottom surface of the trench, and formation of the light shielding material section 20A by filling with the light shielding material.

In conclusion, the manufacturing method for the imaging apparatus 101 of the present embodiment includes the photoelectric converting section forming step S100 of forming the photoelectric converting section 51 on the semiconductor substrate 11, the light shielding section forming step S200 of forming the first light shielding section 12 on the side of the photoelectric converting section 51 corresponding to the first surface 11A of the semiconductor substrate 11, and the charge holding section forming step S300 of forming the charge holding section MEM on the side of the first light shielding section 12 corresponding to the first surface 11A of the semiconductor substrate 11. Further, the first light shielding section 12 includes the light shielding material section 12A including the conductive light shielding material, and the insulating film 12B covering the periphery of the light shielding material section 12A, and is provided, at a partial region of the first light shielding section 12, with the electrically conductive section 12C at which the light shielding material section 12A connects to the semiconductor substrate 11 without intervention of the insulating film 12B.

According to the manufacturing method for the imaging apparatus 101 as described above, the risk of possible arcing during the manufacturing steps is suppressed, enabling manufacture of the imaging apparatus 101 for which possible defects are suppressed.

### 3. Variations

Now, the imaging apparatuses 101 of variations will be described.

### (Variation 1)

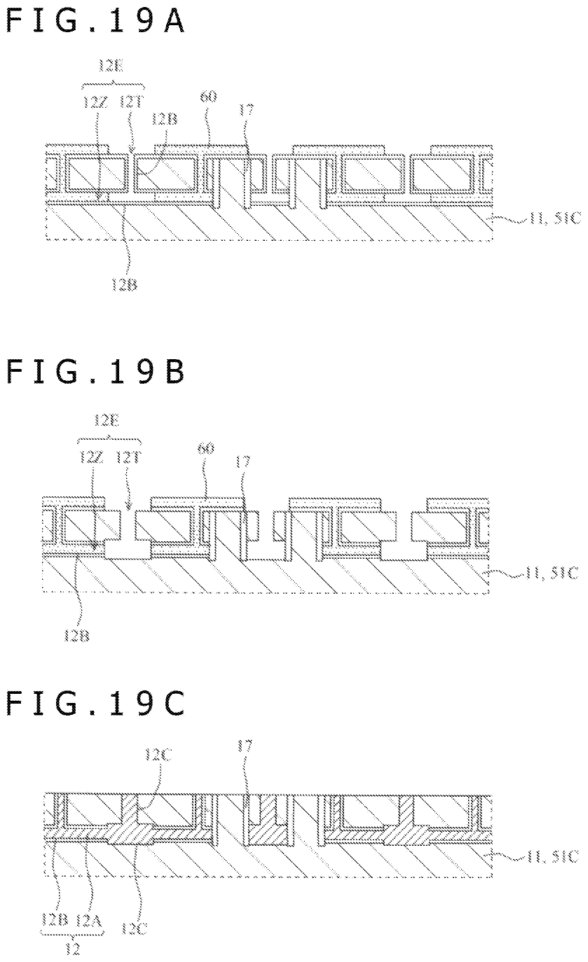

FIGS. 19A to 19C are longitudinal cross-sectional views illustrating the step of forming the first light shielding section 12 of the imaging apparatus 101 of Variation 1.

The imaging apparatus 101 of Variation 1 differs from the imaging apparatus 101 of the present embodiment in which the electrically conductive section 12 includes only the bottom surface of the vertical light shielding portion 12V, in that, in a partial region of the pixel array section 111 of the imaging apparatus 101 of Variation 1, the electrically conductive section 12C includes the whole of the periphery of the vertical light shielding portion 12V and the horizontal light shielding portion 12H of the first light shielding section 12. The rest of the configuration of the imaging apparatus 101 of Variation 1 is the same as that of the present embodiment.

With reference to FIGS. 19A to 19C, a specific example of the step of forming the first light shielding section 12 of the imaging apparatus 101 of Variation 1 will be described. Step S210 of forming the cavity section 12E covered with the insulating film 12B according to Variation 1 is the same as that according to the present embodiment, and thus FIGS. 19A to 19C illustrate only step 220 of removing a part of the insulating film 12B and step 230 of filling the cavity section 12E with the light shielding material.

First, as depicted in FIG. 19A, the resist 60 is applied onto a portion of the insulating film 12B that is to be left instead of being removed during step 220 of removing a part of the insulating film 12B. In this case, the resist 60 that is less viscous than the resist 60 used in the present embodiment is used to fill, with the resist 60, a portion of the horizontal cavity portion 12z corresponding to the region to which the resist 60 is applied.

Next, as depicted in FIG. 19B, isotropic etching is performed to remove a portion of the horizontal cavity portion 12Z that is not filled with the resist 60 and the insulating film 12B on the inner surface of the trench 12T. The isotropic etching is performed by, for example, CDE (Chemical Dry Etching). Thus, in a partial region of the pixel array section 111, the insulating film 12B around the trench 12T and the horizontal cavity portion 12Z is removed.

Finally, as depicted in FIG. 19C, steps similar to those of the present embodiment are used to remove the resist 60, embed, into the cavity section 12E, the light shielding material constituting the light shielding material section 12A, polish and planarize the front surface of the semiconductor substrate 11, and remove the light shielding material and the insulating film 12B on the front surface of the semiconductor substrate 11.

As described above, the imaging apparatus 101 of Variation 1 in which, in a partial region of the pixel array section 111, the electrically conductive section 12C includes the whole of the periphery of the vertical light shielding portion 12V and the horizontal light shielding portion 12H of the first light shielding section 12 is manufactured.

Also in the manufacturing method for the imaging apparatus 101 of Variation 1, the risk of possible arcing during the manufacturing steps is suppressed. Accordingly, for the imaging apparatus 101 of Variation 1, possible defects are suppressed.

### (Variation 2)

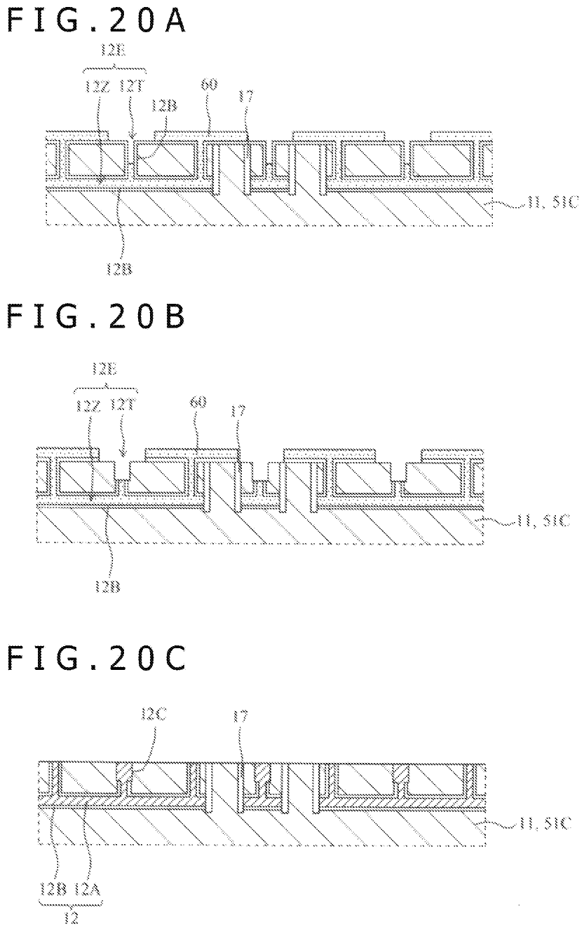

FIGS. 20A to 20C are longitudinal cross-sectional views illustrating the step of forming the first light shielding section 12 of the imaging apparatus 101 of Variation 2.

The imaging apparatus 101 of Variation 2 differs from the imaging apparatus 101 of the present embodiment, in which the electrically conductive section 12 includes only the bottom surface of the vertical light shielding portion 12V, in that, in a partial region of the pixel array section 111 of the imaging apparatus 101 of Variation 2, the electrically conductive section 12C includes a portion of the side surface of the first light shielding section 12 corresponding to the vicinity of an upper end of the vertical light shielding portion 12V. The rest of the configuration of the imaging apparatus 101 of Variation 2 is the same as that of the present embodiment.

With reference to FIGS. 20A to 20C, a specific example of the step of forming the first light shielding section 12 in the imaging apparatus 101 of Variation 2 will be described. Step S210 of forming the cavity section covered with the insulating film according to Variation 2 is the same as that according to the present embodiment, and thus FIGS. 20A to 20C illustrate only step 220 of removing a part of the insulating film 12B and step 230 of filling the cavity section 12E with the light shielding material.

First, as depicted in FIG. 20A, the resist 60 is applied onto a portion of the insulating film 12B that is to be left instead of being removed during step 220 of removing a part of the insulating film 12B. In this case, the resist 60 that is less viscous than the resist 60 used in Variation 1 is used to fill, with the resist 60, a portion of the horizontal cavity portion 12z corresponding to the region to which the resist 60 is applied and further the whole of a portion of the horizontal cavity portion 12Z corresponding to the region to which no resist 60 is applied and a part of the trench 12T.

Next, as depicted in FIG. 20B, isotropic etching is performed to remove a portion of the insulating film 12B on the inner surface of the trench 12T corresponding to the vicinity of the upper end of the trench 12T that is not filled with the resist 60. The isotropic etching is performed by, for example, CDE (Chemical Dry Etching). Thus, in a partial region of the pixel array section 111, a portion of the insulating film 12B on the side surface of the trench 12T corresponding to the vicinity of the upper end of the trench 12T is removed.

Finally, as depicted in FIG. 20C, steps similar to those of the present embodiment are performed to remove the resist 60, embed, into the cavity section 12E, the light shielding material constituting the light shielding material section 12A, polish and planarize the front surface of the semiconductor substrate 11, and remove the light shielding material and the insulating film 12B on the front surface of the semiconductor substrate 11.

As described above, the imaging apparatus 101 of Variation 2 in which, in a partial region of the pixel array section 111, the electrically conductive section 12C includes a portion of the side surface of the first light shielding section 12 corresponding to the vicinity of the upper end of the vertical light shielding portion 12V is manufactured.

Also in the manufacturing method for the imaging apparatus 101 of Variation 2 as described above, the risk of possible arcing during the manufacturing steps is suppressed. Accordingly, for the imaging apparatus 101 of Variation 2, possible defects are suppressed.

### (Variation 3)

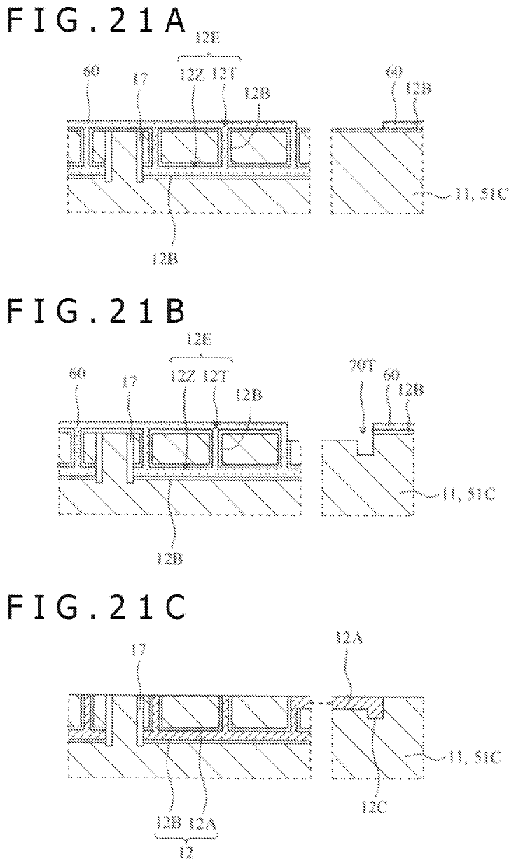

FIGS. 21A to 21C are longitudinal cross-sectional views illustrating the step of forming the first light shielding section 12 of the imaging apparatus 101 of Variation 3.

In the imaging apparatus 101 of Variation 3, the electrically conductive section 12C includes at least a part of the periphery of the light shielding material section 12A extending linearly along the front surface of the semiconductor substrate 11 from the upper end of the vertical light shielding portion 12V of the first light shielding section 12 to an extra-sensor-pixel region. In this case, the extra-sensor-pixel region means a region outside the region where the sensor pixels 121 are disposed. The light shielding material section 12A extending linearly along the front surface of the semiconductor substrate 11 has a structure similar to what is generally called damascene wiring. The light shielding material section 12A of the first light shielding section 12 is integrated with the light shielding material section 12A extending linearly along the front surface of the semiconductor substrate 11.

With reference to FIGS. 21A to 21C, a specific example of the step of forming the first light shielding section 12 of the imaging apparatus 101 of Variation 3 will be described. For this step, Variation 3 is the same as the present embodiment up until step S220 of removing a part of the insulating film 12B.

First, as depicted in FIG. 21A, the resist 60 is applied to the region other than the region extending linearly along the front surface of the semiconductor substrate 11 from the upper end of the vertical light shielding portion 12V of the first light shielding section 12 to the extra-sensor-pixel region.

Next, as depicted in FIG. 21B, for example, dry etching is used to form a trench 70T extending linearly along the front surface of the semiconductor substrate 11 from the upper end of the trench 12T to the extra-sensor-pixel region.

Finally, as depicted in FIG. 21C, steps similar to those of the present embodiment are performed to remove the resist 60, embed, into the cavity section 12E and the trench 70T, the light shielding material constituting the light shielding material section 12A, polish and planarize the front surface of the semiconductor substrate 11, and remove the light shielding material and the insulating film 12B on the front surface of the semiconductor substrate 11.

As described above, the imaging apparatus 101 of Variation 3 in which the electrically conductive section 12C includes at least a part of the periphery of the light shielding material section 12A extending linearly along the front surface of the semiconductor substrate 11 from the upper end of the vertical light shielding portion 12V of the first light shielding section 12 to the extra-sensor-pixel region is manufactured.

Also in the manufacturing method for the imaging apparatus 101 of Variation 3 as described above, the risk of possible arcing during the manufacturing steps is suppressed. Accordingly, for the imaging apparatus 101 of Variation 3, possible defects are suppressed.

### (Variation 4)

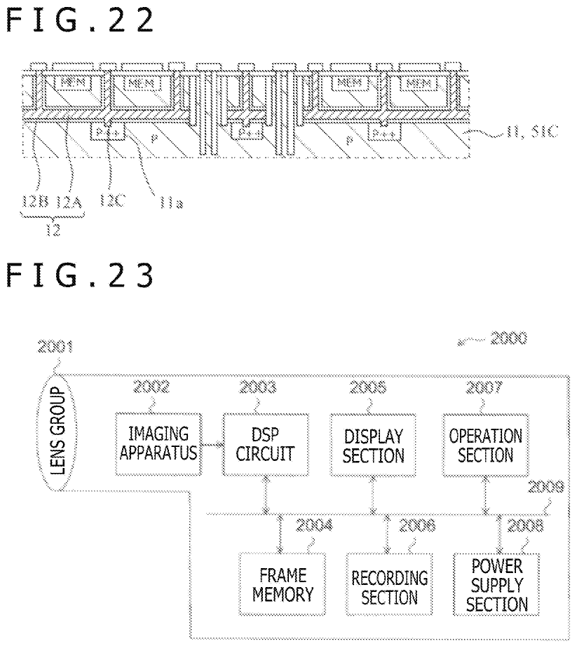

FIG. 22 is a longitudinal cross-sectional view depicting a cross-section structure of the imaging apparatus 101 of Variation 4.

As depicted in FIG. 22, in the imaging apparatus 101 of Variation 4, the electrically conductive section 12C of the first light shielding section 12 includes a region where the light shielding material section 12A comes into contact with a P++ type semiconductor region 11a that is a high-concentration P type region in the semiconductor substrate 11. Here, the high-concentration P type region refers to a P type region having a higher impurity concentration than the P type semiconductor region 51C constituting the photoelectric converting section 51.

This configuration facilitates flow of current through the electrically conductive section 12C, making the potential of the first light shielding section 12 more stable. Accordingly, for the imaging apparatus 101 of Variation 4, the risk of possible arcing is more effectively suppressed.

Further, a range in the semiconductor substrate 11 that is affected by the electrically conductive section 12 can be reduced by the electrically conductive section 12C including the region where the light shielding material section 12A comes into contact with the P++ type semiconductor region 11a in the semiconductor substrate 11. Accordingly, even in a case where the electrically conductive section 12C is provided inside the effective pixel region 111A, a possible dark current can be suppressed to some degree. Thus, even in the imaging apparatus 101 in which the first light shielding section 12 includes the electrically conductive section 12C in the region inside the effective pixel region 111A, in a case where the electrically conductive section 12C includes the region where the light shielding material section 12A comes into contact with the P++ type semiconductor region 11a in the semiconductor substrate 11, then the risk of possible arcing is suppressed to some degree.

### 4. Example of Application to Electronic Equipment

FIG. 23 is a block diagram illustrating a configuration example of a camera 2000 as electronic equipment to which the technology according to the present disclosure is applied.

The camera 2000 includes an optical section 2001 including a lens group, an imaging apparatus (imaging device) 2002 to which the imaging apparatus 101 described above or the like is applied, and a DSP (Digital Signal Processor) circuit 2003 that is a camera signal processing circuit. Moreover, the camera 2000 further includes a frame memory 2004, a display section 2005, a recording section 2006, an operation section 2007, and a power supply section 2008. The DSP circuit 2003, the frame memory 2004, the display section 2005, the recording section 2006, the operation section 2007, and the power supply section 2008 are connected together via a bus line 2009.

The optical section 2001 captures incident light (image light) from a subject to form an image on an imaging surface of the imaging apparatus 2002. The imaging apparatus 2002 converts an amount of incident light formed into an image on the imaging surface by the optical section 2001, into electric signals on a pixel-by-pixel basis, and outputs the electric signals as pixel signals.

The display section 2005 includes, for example, a panel display apparatus such as a liquid crystal panel or an organic EL panel to display videos or still images captured by the imaging apparatus 2002. The recording section 2006 records, in a recording medium such as a hard disk or a semiconductor memory, videos or still images captured by the imaging apparatus 2002.

The operation section 2007 issues operation instructions for various functions of the camera 2000 under the operation of the user. The power supply section 2008 provides various power sources used as operating power sources for the DSP circuit 2003, the frame memory 2004, the display section 2005, the recording section 2006, and the operation section 2007, to these supply targets as appropriate.

By using the above-described imaging apparatus 101 or the like as the imaging apparatus 2002, as described above, good images can be expected to be acquired.

### 5. Example of Application to Mobile Body

The technology according to the present disclosure can be applied to various products. For example, the technology according to the present disclosure may be realized as an apparatus mounted in any type of mobile body such as an automobile, an electric car, a hybrid electric car, a motorcycle, a bicycle, a personal mobility device, an airplane, a drone, a ship, or a robot.

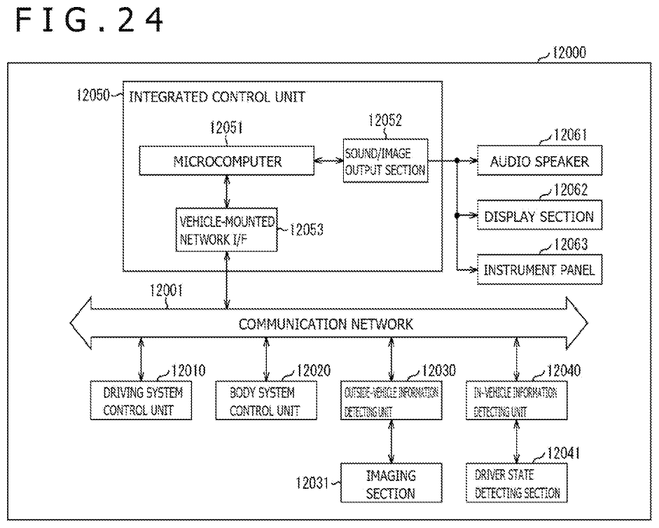

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

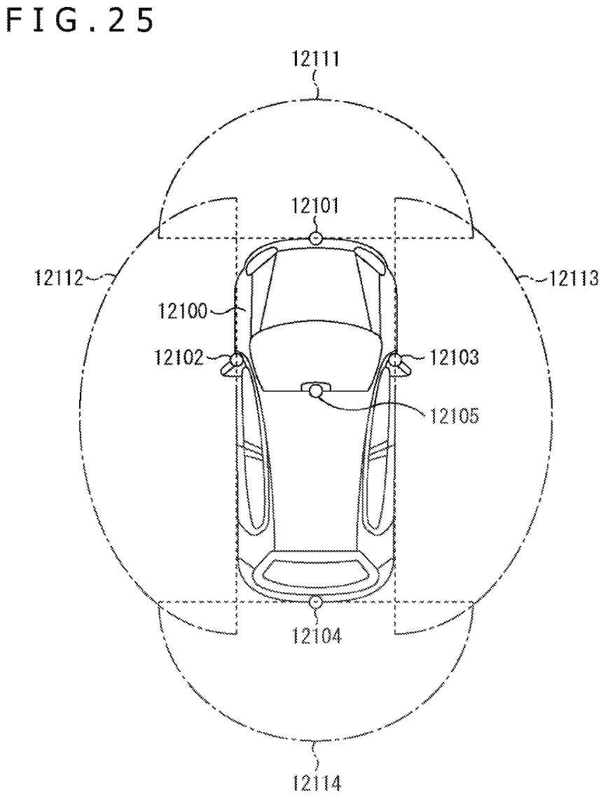

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure may be applied has been described. The technology according to the present disclosure may be applied to the imaging section 12031 of the configuration described above. Specifically, the imaging apparatus 101 and the like depicted in FIG. 1 can be applied to the imaging section 12031. Excellent operations of the vehicle control system can be expected by applying the technology according to the present disclosure to the imaging section 12031.

### 6. Conclusion

An example of the embodiment of the present disclosure has been described. Yet, the present disclosure can be implemented in various other forms. For example, diverse variations, substitutions, omissions, or combinations thereof can be made without departing from the spirits of the present disclosure. Forms resulting from such variations, substitutions, omissions, or the like are included in the scope of the present disclosure and also in the range of the invention recited in claims and equivalents of the invention.

Further, the effects of the present disclosure described herein are only illustrative, and other effects may be produced.

Note that the present disclosure can also take the following configurations.

### [Item 1]

An imaging apparatus including:
a photoelectric converting section that is disposed in a semiconductor substrate and that generates, by photoelectric conversion, charge according to an amount of received light;
a charge holding section that is disposed on a first surface side of the photoelectric converting section corresponding to a first surface of the semiconductor substrate opposite to a light incident surface of the semiconductor substrate and that holds the charge transferred from the photoelectric converting section; and
a light shielding section that is disposed between the photoelectric converting section and the charge holding section and that surrounds at least a part of the charge holding section, in which
the light shielding section includes an electrically conductive section that is a partial region of the light shielding section and that is electrically conductive with the semiconductor substrate.

### [Item 2]

The imaging apparatus according to item 1, in which
the light shielding section includes
   a horizontal light shielding portion spreading in an in-plane direction of the semiconductor substrate between the photoelectric converting section and the charge holding section, and
   a vertical light shielding section shaped like a wall that is extending from the first surface of the semiconductor substrate in a depth direction and that is connected to the horizontal light shielding portion.

### [Item 3]

The imaging apparatus according to item 1 or 2, in which
the light shielding section includes a light shielding material section including a conductive light shielding material, and an insulating film covering a periphery of the light shielding material section, and at the electrically conductive section, the light shielding material section connects to the semiconductor substrate without intervention of the insulating film.

### [Item 4]

The imaging apparatus according to any one of items 1 through 3, in which
the light shielding section does not include the electrically conductive section in an intra-effective-pixel region that is a region inside an effective pixel region of the imaging apparatus but includes the electrically conductive section in an extra-effective-pixel region that is a region outside the effective pixel region.

### [Item 5]

The imaging apparatus according to item 4, in which
the light shielding section includes
   a horizontal light shielding portion spreading in an in-plane direction of the semiconductor substrate between the photoelectric converting section and the charge holding section, and
   a vertical light shielding section shaped like a wall that is extending from the first surface of the semiconductor substrate in a depth direction and that is connected to the horizontal light shielding portion, and
a sequence of the horizontal light shielding portions of the light shielding section is disposed from the intra-effective-pixel region to the extra-effective-pixel region.

### [Item 6]

The imaging apparatus according to any one of items 3 through 5, in which
the electrically conductive section of the light shielding section includes a region where the light shielding material section comes into contact with a high-concentration P type region in the semiconductor substrate.

### [Item 7]

The imaging apparatus according to item 3, in which
the light shielding section includes the electrically conductive section in an intra-effective-pixel region that is a region inside an effective pixel region of the imaging apparatus, and
the electrically conductive section includes a region where the light shielding material section comes into contact with a high-concentration P type region in the semiconductor substrate.

### [Item 8]

The imaging apparatus according to any one of items 1 through 7, in which
the light shielding section includes the electrically conductive section in an internal region spaced from a second surface of the semiconductor substrate that is the light incident surface and from the first surface.

### [Item 9]

The imaging apparatus according to any one of items 1 through 8, in which
the semiconductor substrate includes a silicon substrate.

### [Item 10]

The imaging apparatus according to any one of items 3 through 9, in which
the light shielding material section includes tungsten, titanium, tantalum, nickel, molybdenum, chromium, iridium, platiniridium, titanium nitride, aluminum, copper, cobalt, or a tungsten silicon compound.

### [Item 11]

A manufacturing method for an imaging apparatus, the manufacturing method including:
a photoelectric converting section forming step of forming a photoelectric converting section that generates, by photoelectric conversion, charge according to an amount of received light;
a light shielding section forming step of forming a light shielding section on a first surface side of the photoelectric converting section corresponding to a first surface of the semiconductor substrate opposite to a light incident surface of the semiconductor substrate; and
a charge holding section forming step of forming a charge holding section on the first surface side of the light shielding section corresponding to the first surface of the semiconductor substrate, the charge holding section being at least partly surrounded by the light shielding section and holding the charge transferred from the photoelectric converting section, in which
the light shielding section includes a light shielding material section including a conductive light shielding material, and an insulating film covering a periphery of the light shielding material section, and is provided at a partial region of the light shielding section with an electrically conductive section at which the light shielding material section connects to the semiconductor substrate without intervention of the insulating film.

### [Item 12]

The manufacturing method for the imaging apparatus according to item 11, in which
the light shielding section forming step includes
   a cavity section forming step of forming a cavity section including a horizontal cavity portion spreading in an in-plane direction of the semiconductor substrate between the photoelectric converting section and the charge holding section, and a trench portion that is extending from the first surface of the semiconductor substrate in a depth direction and that is connected to the horizontal cavity portion, the cavity section being covered with the insulating film,
   an insulating film removing step of removing the insulating film in a region corresponding to the electrically conductive section, and
   a light shielding material filling step of filling the cavity section with a light shielding material constituting the light shielding material section.

### [Item 13]

The manufacturing method for the imaging apparatus according to item 12, in which
the insulating film removing step includes
   a resist applying step of applying resist to a resist application region that is a partial region of the first surface of the semiconductor substrate,
   an etching step of removing, by etching, at least a part of the insulating film formed in a portion of the cavity section that is present outside the resist application region, and
   a resist removing step of removing the resist applied in the resist applying step.

### [Item 14]

The manufacturing method for the imaging apparatus according to item 13, in which
the etching step removes, by anisotropic etching, the insulating film on a bottom surface of the trench portion of the cavity section.

### [Item 15]

The manufacturing method for the imaging apparatus according to item 13, in which
the resist applying step applies the resist in such a manner as to fill a portion of the cavity section that is present in the resist application region, with the resist up to the horizontal cavity portion, and
the etching step removes the insulating film in the cavity section by isotropic etching.

### [Item 16]

The manufacturing method for the imaging apparatus according to item 13, in which
the resist application region includes an entire effective pixel region of the imaging apparatus.

### [Item 17]

Electronic equipment including:
an imaging apparatus, in which
the imaging apparatus includes
   a photoelectric converting section that is disposed in a semiconductor substrate and that generates, by photoelectric conversion, charge according to an amount of received light,
   a charge holding section that is disposed on a first surface side of the photoelectric converting section corresponding to a first surface of the semiconductor substrate opposite to a light incident surface of the semiconductor substrate and that holds the charge transferred from the photoelectric converting section, and
   a light shielding section that is disposed between the photoelectric converting section and the charge holding section and that surrounds at least a part of the charge holding section, in which
the light shielding section is electrically conductive with the semiconductor substrate at a partial region of the light shielding section.

### REFERENCE SIGNS LIST

101: Imaging apparatus
111: Pixel array section
111A: Effective pixel region
112: Vertical driving section
113: Ramp wave module
114: Column signal processing section
115: Clock module
116: Data storage section
117: Horizontal driving section
118: System control section
119: Signal processing section
120: Readout circuit
121: Sensor pixel
122: Pixel driving line
123: Vertical signal line
11: Semiconductor substrate
11A: First surface, 11B: Second surface
11a: P++ type semiconductor region
12: First light shielding section
12A: Light shielding material section, 12B:

Insulating film, 12C: Electrically conductive section
12H: Horizontal light shielding portion, 12V: Vertical light shielding portion 12V, 12H1: Opening
12E: Cavity section
12T: Trench, 12Z: Horizontal cavity portion
13: Second light shielding section
13A: Light shielding material section, 13B: Insulating film
13H: Horizontal light shielding portion, 13V: Vertical light shielding portion
15: Fixed charge film
17: Etching stopper
18: Insulating layer
20: Second element isolating section
20A: Light shielding material section, 20B: Insulating film
51, PD: Photoelectric converting section
51A: N− type semiconductor region, 51B: N type semiconductor region, 51C: P type semiconductor region
60: Resist
80: Wiring layer
TRX: Transfer transistor
TRY: Transfer transistor
TRZ: Transfer transistor
HG: Horizontal terminal section, VG: Vertical gate electrode
TRG: Transfer transistor
MEM: Charge holding section
FD: Charge voltage converting section
OFG: Discharge transistor
RST: Reset transistor
AMP: Amplifying transistor
SEL: Select transistor
VDD: Power supply line
VSL: Vertical signal line
CF: Color filter
LNS: Light receiving lens

1. An imaging apparatus comprising:
a photoelectric converting section that is disposed in a semiconductor substrate and that generates, by photoelectric conversion, charge according to an amount of received light;
a charge holding section that is disposed on a first surface side of the photoelectric converting section corresponding to a first surface of the semiconductor substrate opposite to a light incident surface of the semiconductor substrate and that holds the charge transferred from the photoelectric converting section; and
a light shielding section that is disposed between the photoelectric converting section and the charge holding section and that surrounds at least a part of the charge holding section, wherein
the light shielding section includes an electrically conductive section that is a partial region of the light shielding section and that is electrically conductive with the semiconductor substrate.

2. The imaging apparatus according to claim 1, wherein
the light shielding section includes
a horizontal light shielding portion spreading in an in-plane direction of the semiconductor substrate between the photoelectric converting section and the charge holding section, and
a vertical light shielding section shaped like a wall that is extending from the first surface of the semiconductor substrate in a depth direction and that is connected to the horizontal light shielding portion.

3. The imaging apparatus according to claim 1, wherein
the light shielding section includes a light shielding material section including a conductive light shielding material, and an insulating film covering a periphery of the light shielding material section, and at the electrically conductive section, the light shielding material section connects to the semiconductor substrate without intervention of the insulating film.

4. The imaging apparatus according to claim 1, wherein
the light shielding section does not include the electrically conductive section in an intra-effective-pixel region that is a region inside an effective pixel region of the imaging apparatus but includes the electrically conductive section in an extra-effective-pixel region that is a region outside the effective pixel region.

5. The imaging apparatus according to claim 4, wherein
the light shielding section includes
a horizontal light shielding portion spreading in an in-plane direction of the semiconductor substrate between the photoelectric converting section and the charge holding section, and
a vertical light shielding section shaped like a wall that is extending from the first surface of the semiconductor substrate in a depth direction and that is connected to the horizontal light shielding portion, and
a sequence of the horizontal light shielding portions of the light shielding section is disposed from the intra-effective-pixel region to the extra-effective-pixel region.

6. The imaging apparatus according to claim 3, wherein
the electrically conductive section of the light shielding section includes a region where the light shielding material section comes into contact with a high-concentration P type region in the semiconductor substrate.

7. The imaging apparatus according to claim 3, wherein
the light shielding section includes the electrically conductive section in an intra-effective-pixel region that is a region inside an effective pixel region of the imaging apparatus, and
the electrically conductive section includes a region where the light shielding material section comes into contact with a high-concentration P type region in the semiconductor substrate.

8. The imaging apparatus according to claim 1, wherein
the light shielding section includes the electrically conductive section in an internal region spaced from a second surface of the semiconductor substrate that is the light incident surface and from the first surface.

9. The imaging apparatus according to claim 1, wherein
the semiconductor substrate includes a silicon substrate.

10. The imaging apparatus according to claim 3, wherein
the light shielding material section includes tungsten, titanium, tantalum, nickel, molybdenum, chromium, iridium, platiniridium, titanium nitride, aluminum, copper, cobalt, or a tungsten silicon compound.

11. A manufacturing method for an imaging apparatus, the manufacturing method comprising:
a photoelectric converting section forming step of forming a photoelectric converting section that generates, by photoelectric conversion, charge according to an amount of received light;
a light shielding section forming step of forming a light shielding section on a first surface side of the photoelectric converting section corresponding to a first surface of the semiconductor substrate opposite to a light incident surface of the semiconductor substrate; and
a charge holding section forming step of forming a charge holding section on the first surface side of the light shielding section corresponding to the first surface of the semiconductor substrate, the charge holding section being at least partly surrounded by the light shielding section and holding the charge transferred from the photoelectric converting section, wherein
the light shielding section includes a light shielding material section including a conductive light shielding material, and an insulating film covering a periphery of the light shielding material section, and is provided at a partial region of the light shielding section with an electrically conductive section at which the light shielding material section connects to the semiconductor substrate without intervention of the insulating film.

12. The manufacturing method for the imaging apparatus according to claim 11, wherein
the light shielding section forming step includes
a cavity section forming step of forming a cavity section including a horizontal cavity portion spreading in an in-plane direction of the semiconductor substrate between the photoelectric converting section and the charge holding section, and a trench portion that is extending from the first surface of the semiconductor substrate in a depth direction and that is connected to the horizontal cavity portion, the cavity section being covered with the insulating film,
an insulating film removing step of removing the insulating film in a region corresponding to the electrically conductive section, and
a light shielding material filling step of filling the cavity section with a light shielding material constituting the light shielding material section.

13. The manufacturing method for the imaging apparatus according to claim 12, wherein
the insulating film removing step includes
a resist applying step of applying resist to a resist application region that is a partial region of the first surface of the semiconductor substrate,
an etching step of removing, by etching, at least a part of the insulating film formed in a portion of the cavity section that is present outside the resist application region, and
a resist removing step of removing the resist applied in the resist applying step.

14. The manufacturing method for the imaging apparatus according to claim 13, wherein
the etching step removes, by anisotropic etching, the insulating film on a bottom surface of the trench portion of the cavity section.

15. The manufacturing method for the imaging apparatus according to claim 13, wherein
the resist applying step applies the resist in such a manner as to fill a portion of the cavity section that is present in the resist application region, with the resist up to the horizontal cavity portion, and
the etching step removes the insulating film in the cavity section by isotropic etching.

16. The manufacturing method for the imaging apparatus according to claim 13, wherein
the resist application region includes an entire effective pixel region of the imaging apparatus.

17. Electronic equipment comprising:
an imaging apparatus, wherein
the imaging apparatus includes
a photoelectric converting section that is disposed in a semiconductor substrate and that generates, by photoelectric conversion, charge according to an amount of received light,
a charge holding section that is disposed on a first surface side of the photoelectric converting section corresponding to a first surface of the semiconductor substrate opposite to a light incident surface of the semiconductor substrate and that holds the charge transferred from the photoelectric converting section, and
a light shielding section that is disposed between the photoelectric converting section and the charge holding section and that surrounds at least a part of the charge holding section, wherein
the light shielding section includes an electrically conductive section that is a partial region of the light shielding section and that is electrically conductive with the semiconductor substrate.
